(19) United States
(12) Patent Application Publication
(10) Pub. No.: US 2025/0143051 A1
(43) Pub. Date: May 1, 2025

(54) OPTOELECTRONIC SEMICONDUCTOR DEVICE AND METHOD FOR PRODUCING AN OPTOELECTRONIC SEMICONDUCTOR DEVICE

(71) Applicant: ams-OSRAM International GmbH, Regensburg (DE)

(72) Inventors: Susanne BRUNNER, Regensburg (DE); Ivar TANGRING, Regensburg (DE)

(21) Appl. No.: 18/722,494

(22) PCT Filed: Nov. 23, 2022
(86) PCT No.: PCT/EP2022/083000

§ 371 Date: Jun. 20, 2024

(30) Foreign Application Priority Data
Dec. 22, 2021 (DE) 10 2021 214 931.6
Jan. 26, 2022 (DE) 10 2022 200 853.7

(51) Int. Cl. H10H 20/858; H10H 20/01

(52) U.S. Cl. CPC H10H 20/8582; H10H 20/0365; H10H 20/8581; H10H 20/8583; H10H 20/8585

(57) ABSTRACT

The invention relates to an optoelectronic semiconductor device comprising a carrier, an optoelectronic semiconductor chip arranged on the carrier and a plurality of columns, wherein the plurality of columns are arranged on a base surface of the carrier opposite to the optoelectronic semiconductor chip, and wherein the plurality of columns cause a thermal heat conduction away from the optoelectronic semiconductor chip and the carrier. The invention further relates to a method for producing an optoelectronic semiconductor device.

An optoelectronic semiconductor device is specified. In addition, a method for producing an optoelectronic semiconductor device is specified.

This patent application claims the priority of German patent application 10 2022 200 853.7, the content of the disclosure of which is hereby incorporated by reference.

“Submount” light-emitting diode devices are known from the prior art (OSRAM OSLON Submount CL) and are used, for example, in automobile headlights. It is known that these components are conventionally adhesively bonded on a heat sink using a polymer-based adhesive. Furthermore, it is known that such polymer-based adhesives have a low thermal conductivity.

One object to be achieved is to specify an optoelectronic semiconductor device which comprises a second level connection that is distinguished by a particularly high thermal conductivity.

A further object to be achieved is to specify a method for producing such an optoelectronic semiconductor device.

These objects are achieved by a subject matter having the features of independent claim 1 or by a method having the features of independent claim 20. Advantageous embodiments and refinements are the subject matter of the respective dependent claims.

According to at least one embodiment, the optoelectronic semiconductor device comprises a carrier, an optoelectronic semiconductor chip arranged on the carrier, and a plurality of columns, wherein the plurality of columns are arranged on a base surface of the carrier opposite to the optoelectronic semiconductor chip and wherein the plurality of columns cause thermal heat conduction away from the optoelectronic semiconductor chip and the carrier.

The plurality of columns can be adhesively bonded or soldered here onto a substrate, wherein the plurality of columns cause thermal heat conduction away from the optoelectronic semiconductor chip and the carrier to the substrate.

The optoelectronic semiconductor device can advantageously be adhesively bonded or soldered to the carrier comprising the plurality of columns on a substrate, wherein the plurality of columns causes the thermal heat conduction away from the optoelectronic semiconductor chip and the carrier into the second level connection between the carrier and the substrate. Furthermore, if the optoelectronic semiconductor device is soldered onto a substrate, a soldered connection between the plurality of columns and the substrate may advantageously be implemented with particularly low mechanical tensions.

In particular, the optoelectronic semiconductor device has a higher thermal heat conduction in the interface, i.e., the second level connection, between the carrier and a substrate than the light-emitting diode device known from the prior art. In particular, the plurality of columns cause a particularly homogeneous thermal heat conduction in the direction away from the carrier and the optoelectronic semiconductor chip. The increased thermal heat conduction is to be attributed here to a lower thermal resistance (Rth) in the interface between the carrier and the substrate and at the same time ensures a reduction of the thermal resistance of the optoelectronic semiconductor device as the overall device. In particular, the thermal resistance (Rth) between the carrier of the optoelectronic semiconductor device and an adjoining substrate can be reduced by at least between 1 to 50%, or by at least between 5 and 40%, or by at least between 10-30%.

Conventionally, “submount” optoelectronic light-emitting diode devices having aluminum nitride (AlN) carriers (OSRAM OSLON submount CL) are adhesively bonded on a copper or aluminum heat sink. The filled polymer adhesives used often display a low thermal conductivity, which is normally in the range 1-10 W/mK. Direct, full-surface soldering of such light-emitting diode devices onto a printed circuit board is not possible because of differences in the coefficients of thermal expansion between the AlN carrier of the light-emitting diode device and the printed circuit board. In particular, excessively large differences in the coefficients of thermal expansion between the carrier and the printed circuit board can result in cracks and delamination of the soldering. For example, it is also necessary upon adhesive bonding of a thicker adhesive layer to provide the connection between the AlN carrier and the circuit board with sufficient flexibility so that cracks and delamination do not occur in the adhesive layer. The combination of a low thermal conductivity and a thick adhesive layer disadvantageously results in a high thermal resistance in the second level connection, i.e., in the adhesive layer between the carrier of the light-emitting diode device and the printed circuit board. For example, it has been possible to show for a 10 mm² light-emitting diode device which was adhesively bonded using a 40 μm thick adhesive layer, having a thermal conductivity of 7 W/mK, that the adhesive layer has a thermal resistance of approximately 0.5 K/W. This thermal resistance in the adhesive layer or the connection between the carrier of the light-emitting diode device and the substrate can make up more than 20% of the total thermal resistance of the light-emitting diode device and thus limits the maximum power of the light-emitting diode device.

An optoelectronic semiconductor device described here is based, inter alia, on the following considerations that even very little material, i.e., a low total material volume of the plurality of columns which consists of a material having high thermal conductivity can dissipate heat away from the optoelectronic semiconductor chip and the carrier much more efficiently than if only a polymer adhesive is used.

A further advantage is that a connection between materials having very different coefficients of thermal expansion (CTE) can be enabled. For example, the difference in coefficients of thermal expansion between connected materials often results in mechanical tensions. In the intended operation, material fatigue can occur after many thermal cycles in the connection between a carrier of an optoelectronic semiconductor chip and a substrate.

A soft material, such as a polymer-based adhesive, in the connection between the carrier and the substrate can usually absorb differences in the coefficients of thermal expansion between the materials and reduce the mechanical tensions. However, such materials also disadvantageously have generally low thermal conductivities and high thermal resistances.

The optoelectronic semiconductor device according to the invention can advantageously in particular comprise a carrier made of a very hard material, having a high modulus of elasticity and low coefficient of thermal expansion, which is soldered directly together with a metallic substrate without excessive material tensions and material failure occurring.

According to at least one embodiment, the optoelectronic semiconductor device comprises a carrier or a housing comprising one of the following materials: aluminum nitride, aluminum oxide, silicon nitride, silicon carbide, or diamond. In particular, carrier or housing materials made of silicon carbide or diamond can advantageously be used. Both materials have high moduli of elasticity and low coefficients of thermal expansion and thus cause strong tensions when they have been soldered directly together with a metallic heat sink. However, both materials are also distinguished by high thermal conductivities and therefore can advantageously be used as a carrier or housing material.

According to at least one embodiment, the optoelectronic semiconductor device comprises a plurality of columns made of metal. In particular, the plurality of columns consists of copper or a copper-containing alloy. The plurality of columns can also consist, for example, of gold or a gold-containing alloy. In particular, the plurality of columns preferably comprises a material having good thermal conductivity or electrical conductivity. The plurality of columns can comprise different subsets which comprise different materials. By way of the use of different materials for different subsets of the plurality of columns, in particular the material properties of the various subsets from the plurality of columns can be individually set. In particular, electrical and/or thermal conductivities of subsets from the plurality of columns can be individually set via the material selection. Furthermore, the use of different materials for different subsets of the plurality of columns permits particularly cost-effective and resource-efficient production to be ensured. For example, some subsets of the plurality of columns can consist of gold or a gold alloy, wherein other subsets consist of copper or a copper alloy. Furthermore, the material for the plurality of columns or subsets thereof can be selected so that a certain specific electrical or thermal resistance is provided. The electrical or thermal resistance over one column or over the plurality of columns or over a subset of the plurality of columns can thus be set as a function of the length and/or the cross-sectional area of the one column or the plurality of columns.

According to at least one embodiment, the optoelectronic semiconductor device comprises at least one column of the plurality of columns having an aspect ratio, wherein the width of at least one column is shorter than its height. The plurality of columns preferably has an aspect ratio of greater than 1. In particular, due to the use of a plurality of columns having an aspect ratio greater than 1, the adhesives or soldered connection between the carrier of the optoelectronic semiconductor device and the substrate can be made particularly mechanically flexible. For example, the narrower and longer the plurality of columns are and the farther away they are arranged from one another on the carrier, the more flexible can the connection between the carrier and the substrate be made. In particular, due to the use of a plurality of columns having an aspect ratio greater than 1, an adhesive or soldered connection between the carrier and the substrate having lower mechanical tensions with improved thermal connection may be implemented.

According to at least one embodiment, the optoelectronic semiconductor device comprises at least one column of the plurality of columns having an aspect ratio, wherein a width of at least one column is longer than its height. Particularly mechanically stable columns or subsets of the plurality of columns may thus be produced. For example, individual columns or subsets of the plurality of columns having a width which is longer than its height can be provided. Individual columns or subsets of the plurality of columns can thus advantageously function as mechanically stable spacers. In particular, by providing individual columns or subsets of the plurality of columns which are more mechanically stable than the rest, it is possible for the plurality of columns to be less susceptible to mechanical deformation during the further handling or the production process, in particular during the connection process. For example, at least one column from the plurality of columns can have a width which is longer than its height and at least one subset from the plurality of columns can have a width which is shorter than its height. All columns may have the same height. A plurality of columns may thus advantageously be provided which cannot be mechanically deformed in the vertical direction, parallel to the lateral surfaces of the plurality of columns, wherein the plurality of columns which have a width which is less than its height can nonetheless provide the mechanical flexibility with respect to differences in coefficients of thermal expansion between the carrier and the substrate. The at least one column, having the width which is longer than the height, functions as a mechanically stable spacer, and the at least one subset of the plurality of columns, having the width which is shorter than the height, make it possible that a mechanically flexible connection can be ensured between the carrier and the substrate.

The plurality of columns can have a height between 5 μm and 200 μm, or preferably a height between 10 μm and 100 μm, or particularly preferably a height between 20 μm and 60 μm. In particular, a column height of 40 μm has proven to be particularly favorable. For example, the height of the plurality of columns can be selected according to the required polymer material joint or the required distance between the carrier and the substrate. For example, the polymer material joint between the carrier and the substrate can be deliberately controlled by the selected height of the plurality of columns. The plurality of columns can have the same height here. In this way, the polymer material joint between the carrier and the substrate can be created equally over the entire base surface of the carrier. Alternatively, a subset of the plurality of columns can have a height different from another subset of the plurality of columns. A substrate having a topological surface or multiple substrates which are arranged at different heights to one another could thus be used. Different subsets from the plurality of columns are arranged on different level heights on one or more substrates.

According to at least one embodiment, the optoelectronic semiconductor device comprises a plurality of columns, wherein the total surface added together of the end faces of the plurality of columns is at least 10 to 30% of the base surface of the carrier. In general, a larger total surface of the plurality of columns, at equal height, has the effect that more heat can be dissipated through the plurality of columns in the direction of the substrate. For example, at least one column from the plurality of columns has a width which is less than the height. For example, at least one column from the plurality of columns has a width which is less than 200 μm, or is less than 100 μm, or is less than 60 μm, or is less than 40 μm, or is less than 20 μm, or is less than 10 μm, or is less than 5 μm. In particular, a column width of less than 40 μm has proven to be particularly favorable in order to increase a mechanical adhesion of the plurality of columns in a solder or in an adhesive. For example, a particularly good mechanical adhesion was ensured with a column height of 40 μm and a column width less than 30 μm, or a column width less than 20 μm, or a column width less than 10 μm, or a column width less than 5 μm.

According to at least one embodiment, the optoelectronic semiconductor device comprises at least one column from the plurality of columns which in cross section has a geometric shape that is circular and/or ellipsoidal and/or square and/or polygonal, in particular triangular, quadrangular, pentagonal, hexagonal, or octagonal. Circular, triangular, quadrangular, and hexagonal columns may advantageously moreover be packed together particularly closely in a matrix consisting of a plurality of columns.

According to at least one embodiment, the optoelectronic semiconductor device comprises at least one subset of the plurality of columns which are arranged equidistantly from one another on the carrier. The expression “equidistant” in this context means that all columns are distanced equally from one another. In particular, the center point of one column is arranged at the same distance from the center point of an adjacent column. Different subsets of the plurality of columns can have different equidistant distances of the columns.

According to at least one embodiment, the optoelectronic semiconductor device comprises at least one first row of columns in a matrix of the plurality of columns or a subset of columns from the plurality of columns which have a different column distance on the carrier than a second row or a second subset of columns. For example, a first row of columns in a matrix of the plurality of columns, with equal row lengths, can thus be equipped with a different number of columns than a second or third row. Furthermore, a first subset of columns in a matrix of the plurality of columns, with equal subset area, can thus be equipped with a different number of columns than a second or third subset. In particular, rows and/or subsets of columns having different electrical, thermal, or mechanical properties may thus be provided. For example, a first row or a first subset of columns can be equipped with a higher number of columns than a second row or a second subset of columns. Rows and/or subsets of the plurality of columns may preferably thus be provided which can electrically supply an area of the carrier particularly reliably and/or can dissipate a particularly large amount of heat. Furthermore, the mechanical property of the adhesive or soldered connection between the plurality of columns and the substrate can be controlled in the area of a row or a subset of columns by the number of columns within a row or subset of columns. For example, particularly stable mechanical adhesive bonds or soldered connections may be implemented if the column height is 40 μm and the total area added together of the end faces of the plurality of columns is at least 30% or at least 20% or at least 10% of the base surface of the carrier.

According to at least one embodiment, the optoelectronic semiconductor device comprises a polymer which is present between the plurality of columns, the base surface of the carrier and the upper side of the substrate, and the end faces of the plurality of columns and the upper side of the substrate. The optoelectronic semiconductor device is fastened here using the polymer on the substrate.

The polymer is preferably in direct contact with the base surface of the carrier, the upper side of the substrate, the end faces of the plurality of columns, and with the lateral surfaces of the plurality of columns. A direct contact has the effect that a particularly reliable and mechanically stable material bond can be ensured. The polymer preferably wets the base surface of the carrier, the upper side of the substrate, and the at least one lateral surface of the plurality of columns comprehensively. The polymer preferably only wets the base surface of the carrier comprehensively where the plurality of columns are not arranged on the carrier. The polymer wets the base surface of the carrier, the upper side of the substrate, and the at least one lateral surface of the plurality of columns by at least 50%, or preferably at least 75%, or more preferably at least 95% here.

In particular, an adhesive layer is formed between the end faces of the plurality of columns and the substrate. The polymer layer between the end faces of the plurality of columns and the upper side of the substrate is preferably as thin as possible to ensure a low thermal resistance between the end faces of the plurality of columns and the substrate. The thickness of the polymer layer between the end faces of the plurality of columns and the upper side of the substrate is at most 5 μm, or at most 3 μm, or at most 1 μm. The polymer layer covers the end faces of the plurality of columns by at least 20%, preferably by at least 50%, more preferably by at least 75%. With a 20% coverage of the end faces and a thickness of the polymer layer of 1 μm, it was possible to reduce the thermal resistance, for example, from 0.6 K/W to 0.1 K/W, in comparison to the end faces of the plurality of columns which are not covered.

For example, a high surface coverage of the polymer has the effect that a stable and reliable material bond can be ensured. In particular, the plurality of columns increases the contact area of the polymer in the adhesive bond between the carrier and the substrate. The increased contact area of the polymer causes an improved adhesion of the polymer. Furthermore, a high surface coverage of the polymer also contributes to improved heat conduction. In particular, the good surface coverage of the polymer with the lateral surfaces of the plurality of columns has the effect in the case of a partial delamination between the end faces of the plurality of columns and the substrate that good adhesion and heat conduction to the substrate can always be ensured.

In particular, the polymer is an adhesive. For example, the adhesive is based on silicone or epoxy resin. The plurality of columns has the effect that an improved heat conduction is created in the adhesive bond between the carrier and the substrate. The increased heat conduction is to be attributed to the plurality of columns, which are used to guide the heat through the adhesive in the direction of the substrate. For example, a thin adhesive layer may be present between the end faces of the plurality of columns and the substrate. A particularly low thermal resistance may thus be created in the interface between the end faces of the plurality of columns and the substrate.

According to at least one embodiment, the optoelectronic semiconductor device comprises a polymer which comprises filler materials. In particular, the polymer is an adhesive. For example, the adhesive is based on silicone or epoxy resin. The adhesive can contain additional filler materials in order to influence the properties of the adhesive. The filler materials are preferably added as a powder. For example, the filler materials can be materials having high dielectric strength or electrically insulating materials. For example, the use of such filler materials together with an electrically insulating polymer allows short-circuits to be avoided between two differently polarized and electrically conductive subsets of the plurality of columns. The use of ZnO-based or SiC-based varistors has proven to be particularly suitable filler materials. For example, the insulators are in particular ceramic or amorphous materials such as glass. For example, the filler material can comprise aluminum oxide, aluminum nitride, silicon nitride, or silicon carbide.

Alternatively, filler materials which have particularly high thermal conductivity can also be used for the adhesive. In particular, particles made of silver or silver alloys are used as filler materials for the adhesive. For example, the thermal conductivity of the adhesive may thus be increased, wherein the contribution of the adhesive to the heat conduction in the direction of the substrate can be increased.

According to at least one embodiment, the optoelectronic semiconductor device has a maximum polymer material joint between the carrier and the substrate which is determined by the height of the plurality of columns. A polymer material joint may thus be implemented, for example, which reproducibly has the same height everywhere between a base surface of the carrier and an upper side of a substrate. In particular, a homogeneous heat conduction in the direction away from the optoelectronic semiconductor device and the carrier to the substrate may thus be implemented. Furthermore, a comprehensively homogeneous heat conduction in the direction away from the optoelectronic semiconductor chip and the carrier toward the substrate may be generated over the entire carrier. A homogeneous heat dissipation from the optoelectronic semiconductor chip and the carrier can contribute to the increased service life of the optoelectronic semiconductor chip. The plurality of columns can be adhesively bonded or soldered onto the substrate. A particularly well defined and controllable polymer material joint may be created if the plurality of columns are firmly bonded to the substrate. In particular, if the plurality of columns are firmly soldered on the substrate, there are no thickness differences of the polymer material joint between the carrier and the substrate. A polymer material joint between the carrier and the substrate which has a differing thickness under the carrier results in particular in a differing thermal resistance between the carrier and the substrate. In particular, the optoelectronic semiconductor device has a lower thermal resistance between the carrier and the substrate if the plurality of columns are arranged having their end faces directly adjoining the substrate.

According to at least one embodiment, the optoelectronic semiconductor device comprises a polymer which laterally overflows the base surface of the carrier.

According to at least one embodiment, the optoelectronic semiconductor device comprises a polymer which adjoins a carrier end side. For example, the excess polymer for the adhesive bond, which laterally overflows the base surface of the carrier, can slightly rise up or adjoin the carrier end side. The expression “slightly” in this context means that the polymer rises up at least 10%, or at least 30%, or at least 50% from the height of the carrier end side. The excess polymer which laterally overflows the base surface of the carrier can run inclined from the surface of the substrate to the end side of the carrier. For example, a particularly reliable adhesive bond may be created between the carrier and the substrate if the polymer adjoins and adheres to the carrier end side. In particular, the optoelectronic semiconductor device thus better withstands mechanical shear stresses.

According to at least one embodiment, the optoelectronic semiconductor device comprises a polymer end side which terminates flush with the carrier end side. Such optoelectronic semiconductor devices are preferably particularly space-saving and may be placed closer to other optoelectronic semiconductor devices and/or other electronic components.

According to at least one embodiment, the optoelectronic semiconductor device comprises a polymer which fixes the plurality of columns on the substrate. The expression “fixing” in this context means that the polymer mechanically stabilizes the plurality of columns. That is to say, the polymer network between the columns causes the plurality of columns to bear compressive, shear, or tension forces better. For example, the polymer network has the effect that the plurality of columns does not plastically deform or bend during the handling or in operation. In particular, the fixing of the plurality of columns by the polymer has the effect that columns having high aspect ratios (aspect ratios=height of a column in relation to width of the column) and/or columns which have a large distance from one another can be used. For example, the plurality of columns has an aspect ratio of greater than 1, or greater than 2, or greater than 3, or greater than 5, or greater than 10. The distance of the individual columns is greater than the width of one column from the plurality of columns. For example, the distance is more than 2 times the column width, or more than 5 times the column width, or more than 10 times the column width, or more than 20 times the column width.

According to at least one embodiment, the optoelectronic semiconductor device comprises a substrate which comprises a circuit board. The substrate can be formed, for example, as a printed circuit board (PCB). In particular, the circuit board comprises electrical lines. The circuit board can furthermore be formed as a printed metal core circuit board. The circuit board can comprise, for example, a metal core made of copper or aluminum. The circuit board preferably functions as a heat sink for heat which is generated in the optoelectronic semiconductor device and is conducted via the carrier having the plurality of columns to the substrate.

According to at least one embodiment, the circuit board comprises at least one of the following materials: aluminum, copper, aluminum oxide, silicon nitride, aluminum nitride, FR4.

According to at least one embodiment, the optoelectronic semiconductor device comprises a first circuit board, which comprises electrical conductor tracks and/or comprises at least one exposed area having metal which extends perpendicular to and in the direction away from the carrier base surface through the circuit board and functions as a heat conductor, connection surface, and/or electrical conductor.

According to at least one embodiment, the optoelectronic semiconductor device comprises a plurality of columns which are arranged directly above, in contact with, or connected to the exposed area having metal on the circuit board. A polymer or a solder can be present here between the end faces of the plurality of columns and the substrate, which additionally fastens the plurality of columns on the substrate.

According to at least one embodiment, the optoelectronic semiconductor device comprises a plurality of columns, each of which comprises an end cap consisting of solder. The end caps have the effect that the plurality of columns are able to be soldered on the substrate. The optoelectronic semiconductor device having the carrier, comprising the plurality of columns, can preferably thus be fastened using the end caps on the substrate. For example, the solder comprises an alloy which comprises at least two of the following elements: Ag, Al, Au, Bi, Cd, Cu, Fe, P, Pb, Sb, Si, Sn, Zn. In particular, the end caps can comprise gold-tin (AuSn) or silver-tin-copper (SnAgCu) based solder. For example, the substrate can be a heat sink. In particular, the heat sink can be a circuit board comprising copper or aluminum.

According to at least one embodiment, the optoelectronic semiconductor device comprises a plurality of columns, which each comprise an end face facing away from the base surface of the carrier, and at least one laterally circumferential lateral surface, which is aligned perpendicular to the end face, wherein the end cap of at least one column from the plurality of columns covers the end face and at least partially the at least one laterally circumferential lateral surface with the solder. For example, the material bond between the plurality of columns and the substrate may be created particularly mechanically stably if the end caps cover both the end faces and at least partially the at least one laterally circumferential lateral surface with the solder. The fact that the end caps at least partially cover the lateral surfaces causes an increased connection area to be able to be created for the soldered connection, wherein the solder wets both the end faces of the plurality of columns, the substrate, and at least partially the at least one laterally circumferential lateral surface. The term “partially” in this context means that the height of the end caps in the direction facing away from the upper side of the substrate is at most 5% or at most 10% or at most 20% or at most 50% of the height of a column from the plurality of columns. The thickness of the end caps is preferably between 500 nm and 10 μm here, or preferably between 1 and 6 μm, or more preferably between 2 and 4 μm. In particular, a thickness of approximately 3 μm has proven to be particularly advantageous.

According to at least one embodiment, the optoelectronic semiconductor device comprises end caps which provide a mechanical and a thermal and/or an electrical connection. In particular, the end caps have the effect that a reliable mechanical and thermal and/or electrical soldered connection can be created between the carrier having the plurality of columns and the substrate. The plurality of columns preferably has the effect that a difference in coefficients of thermal expansion between the carrier and the substrate can be compensated for particularly advantageously. The plurality of columns have the effect here that the thermal tensions in the soldered connection between the carrier and the substrate can be reduced. This is to be attributed both to a small overall surface, in comparison to a full-surface soldered connection, between the plurality of columns and the substrate, and to the interrupted soldered connection. Furthermore, the plurality of columns which are fastened using the end caps made of solder on the substrate comprises an integral material bond between the end faces of the plurality of columns and the substrate. A connection which is particularly advantageous for the thermal and/or electrical conductivity thus results, which has a particularly low thermal and electrical resistance.

According to at least one embodiment, the optoelectronic semiconductor device comprises a polymer between the base surface of the carrier and an upper side of a substrate, wherein the upper side of the substrate is arranged directly adjoining below the end faces of the plurality of columns. The plurality of columns are connected using the end caps made of solder to the substrate. In particular, in this case no polymer is present between the end faces of the plurality of columns and the upper side of the substrate. In particular, in this case the polymer completely fills the area between the plurality of columns and the area between the carrier and the substrate. The polymer preferably comprehensively covers the lateral surfaces of the plurality of columns, the lateral edges of the end caps aligned perpendicular to the substrate, and the carrier and the substrate where the plurality of columns are not arranged.

According to at least one embodiment, the optoelectronic semiconductor device optionally comprises a polymer in the intermediate spaces of the plurality of columns. For example, the polymer, in addition to the end caps made of solder, contributes to the adhesion in the connection between the carrier having the plurality of columns and the substrate. The polymer increases the mechanical stability of the plurality of columns and/or of the soldered connections between the end caps and the substrate in this case. The polymer preferably fills the entire volume between the plurality of columns and between the carrier and the substrate in this case. Adequate underfilling of the polymer between the carrier and the substrate has the effect that few air bubbles are present under the carrier and between the plurality of columns. This in turn causes better adhesion between the carrier and the substrate. The heat conduction through the plurality of columns is much higher here than the heat conduction through the polymer, so that polymer materials other than adhesive can be used, the properties of which have been optimized for improved adhesion or an adapted coefficient of thermal expansion. For example, polymers without further filling materials can thus advantageously be used as the adhesive. The addition of further filler materials which do not contribute to the adhesion can have a negative effect on the adhesion.

According to at least one embodiment, the optoelectronic semiconductor device comprises a substrate which comprises at least one baseplate. In particular, the baseplate is a metal plate. The metal plate can preferably consist of copper or a copper alloy. The metal plate can have a thickness here between 1 mm and 5 μm, or preferably a thickness between 500 μm and 20 μm, or particularly preferably a thickness between 150 μm and 50 μm.

According to at least one embodiment, the optoelectronic semiconductor device comprises at least one baseplate. The baseplate can be provided here as a block, film, plate, or layer. For example, the at least one baseplate can comprise one or more pre-structured parts or the at least one baseplate is only structured after the connection to the plurality of columns.

For example, a baseplate which is assigned to a subset of the plurality of columns can have a shape and at least one surface which corresponds to the plurality of columns arranged on the base surface of the carrier. A baseplate which is assigned to a subset of the plurality of columns can preferably have a shape in the top view which corresponds to an outer contour of this subset. The shape and area of a baseplate which is assigned to a subset of the plurality of columns is not restricted by the shape of this subset of the plurality of columns, but rather can have any shape and surface which also extends outside the outer contour of the plurality of columns. In particular, the shape and area of the baseplate can be adapted to the thermal and electrical requirements of the optoelectronic semiconductor device. In principle, a baseplate which is larger than the assigned subset of the plurality of columns has the effect that heat that is conducted from the carrier and the optoelectronic semiconductor device in the direction of a heat sink or circuit board can be divided temporarily onto a larger area than the area occupied by the plurality of columns.

According to at least one embodiment, the optoelectronic semiconductor device comprises a carrier having a plurality of columns which are fastened using end caps on the at least one baseplate. In particular, the plurality of columns are soldered using end caps made of solder onto the upper side of a baseplate. In this case, the baseplate forms a new underlying surface for the optoelectronic semiconductor device or for the carrier having the plurality of columns. The end caps can preferably consist of a AuSn solder layer. The thickness of the end caps is preferably between 500 nm and 10 μm, or preferably between 1 and 6 μm, or more preferably between 2 and 4 μm here. In particular, a thickness of the end caps of approximately 3 μm has proven to be sufficiently thick to ensure a reliable soldered connection between the plurality of columns and the baseplate.

According to at least one embodiment, the optoelectronic semiconductor device comprises a polymer between the carrier and the baseplate. The optoelectronic semiconductor device comprises a carrier having a plurality of columns, which are fastened using end caps made of a solder to the baseplate. For example, the carrier comprises a silicone or epoxy between the plurality of columns. The polymer can be introduced here by foil-assisted molding (FAM), dispensing, squeegeeing, casting, or molding between the plurality of columns, wherein the plurality of columns is free of the polymer between the end caps in the lateral direction. For example, the polymer between the plurality of columns ensures that the plurality of columns are more mechanically stable with respect to shear and compressive forces. In particular, a more reliable connection may thus be created between the plurality of columns and the baseplate. The polymer supports the plurality of columns here, so that the columns do not bend or plastically deform during the handling. Bending or plastic deformation of the plurality of columns could cause a mechanical stress of the soldered connections between the plurality of columns having the end caps and the baseplate. The mechanical stress of the soldered connection can as a consequence result in material failures in the soldered connections. Furthermore, it is ensured that the baseplate maintains its shape. In particular, the polymer between the carrier and the baseplate, and between the plurality of columns, has the effect that the baseplate maintains its planarity.

According to at least one embodiment, the optoelectronic semiconductor device comprises one or more subsets of the plurality of columns which provide an electrical contact of the optoelectronic semiconductor device. The subset of the plurality of columns preferably provides both an electrical contact and a thermal contact. For example, a first subset of the plurality of columns can provide an anode and the second subset of the plurality of columns can provide a cathode. In particular, the anode and the cathode provide electrical feeds in order to energize the optoelectronic semiconductor chip. The plurality of columns which provide the anode end at a first via extending through the carrier and the plurality of columns that provide the cathode end at a second via extending through the carrier. The first and second subset of the plurality of columns which are used for the anode and cathode are in particular provided electrically insulated from one another here. The optoelectronic semiconductor device can comprise more than one first and one second subset of the plurality of columns here. Preferably, the optoelectronic semiconductor device can comprise three subsets of the plurality of columns, wherein a first and a second subset of the plurality of columns provide an electrical and a thermal contact, and wherein a third subset of the plurality of columns provides a thermal contact. The third subset of the plurality of columns is in particular provided in an electrically neutral manner.

According to at least one embodiment, the optoelectronic semiconductor device comprises a plurality of columns which are arranged in distinct delimited electrically insulated subsets on the carrier. If, for example, subsets from the plurality of columns are used as electrical lines or contacts, the use of a polymer in the intermediate spaces of the plurality of columns in particular permits electrical short-circuits to be avoided. The dielectric strength can be increased by the use of a filler material, such as a ceramic or a varistor. The susceptibility to electrical short-circuits may thus be suppressed in particular.

According to at least one embodiment, the optoelectronic semiconductor device comprises at least one baseplate which comprises multiple parts. For example, a first subset of the plurality of columns can be connected to a first baseplate and a second subset from the plurality of columns can be connected to a second baseplate and a third subset of the plurality of columns can be connected to a third baseplate. The different baseplates can provide functions different from one another in conjunction with the different subsets of the plurality of columns. For example, a first baseplate and a first subset of the plurality of columns and/or a second baseplate and a second subset of the plurality of columns can provide an electrical and thermal contact. Furthermore, a third baseplate and a third subset of the plurality of columns can provide a thermal contact. For example, a first baseplate and a first subset of the plurality of columns can provide an anode and the second baseplate and second subset of the plurality of columns can provide a cathode. In particular, the first baseplate having the first subset of the plurality of columns is provided electrically insulated from the second baseplate having the second subset of the plurality of columns. A third baseplate having a third subset of the plurality of columns can in particular be provided in an electrically neutral manner. In particular, the third subset of the plurality of columns is arranged on the base surface of the carrier opposite to the semiconductor chip directly below the semiconductor chip on the carrier. The center point of the third plurality of columns deviates here by at most 500 μm, preferably at most 100 μm, or more preferably at most 20 μm from the center point of the semiconductor chip. The number of baseplates and subsets of the plurality of columns is not restricted to three, but rather can be any arbitrary number of baseplates and subsets of the plurality of columns. In particular, an arbitrary number of electrical and thermal connections can be provided on the carrier and the optoelectronic semiconductor device.

According to at least one embodiment, the optoelectronic semiconductor device comprises on the carrier a first subset of the plurality of columns having a first baseplate, a second subset of the plurality of columns having a second baseplate, and a third subset of the plurality of columns having a third baseplate. The first, second, and third baseplate are provided separately from one another. The first subset of the plurality of columns having the first baseplate and the second subset of the plurality of columns having the second baseplate provide an electrical and thermal contact here. In particular, the first subset of the plurality of columns having the first baseplate provides an anode. The second subset of the plurality of columns having the second baseplate provides a cathode here. The third subset of the plurality of columns having the third baseplate provides a thermal contact here. A polymer is preferably arranged between the carrier and the first, second, and third baseplate, and between the first, second, and third subsets of the plurality of columns. The polymer comprehensively covers the base surface of the carrier, where the plurality of columns are not arranged.

According to at least one embodiment, the optoelectronic semiconductor device comprises at least one baseplate which comprises a metal. The baseplate preferably comprises a metal. In particular, the baseplate comprises a metal having high thermal conductivity. For example, the baseplate can comprise copper or a copper-containing alloy.

According to at least one embodiment, the optoelectronic semiconductor device comprises a baseplate which comprises a solder layer on a lower side facing away from the optoelectronic semiconductor chip. The solder layer covers the lower side of the at least one baseplate over the full surface or at least fractionally. For example, the optoelectronic semiconductor device is connected using the solder layer to the baseplate having a heat sink. For example, the optoelectronic semiconductor device is soldered using the solder layer on a heat sink. The plurality of columns arranged between the carrier and the baseplate in particular compensate here for the differences in coefficients of thermal expansion between the carrier and the heat sink. In particular, a carrier of the optoelectronic semiconductor device which comprises ceramic can thus be soldered using the plurality of columns and the baseplate onto a heat sink, comprising a metal. The carrier can comprise aluminum oxide, aluminum nitride, silicon carbide, silicon nitride, graphite, or diamond in this case. The carrier preferably consists of a material having good electrical insulation. The heat sink can preferably comprise copper or aluminum here.

According to at least one embodiment, the optoelectronic semiconductor device comprises at least one baseplate, which is fastened using a solder layer on a circuit board or a heat sink. An optoelectronic semiconductor device which comprises a carrier having multiple subsets of the plurality of columns and multiple baseplates assigned to the plurality of columns can preferably be arranged on a structured circuit board. For example, a metal core circuit board is used. The metal core circuit board comprises, for example, a dielectric passivation layer made of FR4, which is adhesively bonded on a metal core. Alternatively, the metal core can be coated with a dielectric passivation layer made of ceramic. The ceramic layer is arranged directly on the metal core here. The metal core can consist of copper or aluminum. The dielectric passivation layer can cover the metal core completely or fractionally here. If the dielectric passivation layer only covers the metal core fractionally, the metal core can preferably be provided fractionally exposed. The dielectric passivation layer made of FR4 or ceramic can furthermore comprise contact layers. One or more optoelectronic semiconductor devices can be equipped on the metal core circuit board. The metal core circuit board comprises at least as many contact layers and exposed areas having metal as optoelectronic semiconductor devices equipped on the metal core circuit board and baseplates assigned to the optoelectronic semiconductor devices. Some baseplates can be assigned here to the contact layers and others can be assigned to the exposed areas having metal. For example, the baseplates used for electrical energizing are soldered onto the respective contact layers of the dielectric passivation layer. For example, the first plurality of columns, comprising a first baseplate, is soldered onto a first contact layer of the dielectric passivation layer and the second plurality of columns, comprising a second baseplate, is soldered onto a second contact layer of the dielectric passivation layer. For example, the third plurality of columns, comprising a third baseplate, can be soldered onto an exposed area having metal of the metal core. Alternatively, the third plurality of columns, comprising a third baseplate, can be soldered onto a third contact layer of the dielectric passivation layer. The contact layers on the circuit board can comprise copper or a copper alloy, gold or a gold alloy, silver or a silver alloy, or an alloy comprising at least two of the following materials: platinum, palladium, rhodium, ruthenium, iridium, nickel, cobalt, copper, tin, gold, or silver. In particular, the contact layers comprise copper or a copper alloy or gold or a gold alloy. The contact layers can preferably provide an electrical contact, wherein the exposed areas of the metal core provide a thermal contact.

According to at least one embodiment, the optoelectronic semiconductor device comprises a circuit board which comprises at least one exposed area having metal, which extends perpendicular to and in the direction away from the carrier base surface through the circuit board, wherein the at least one exposed area having metal functions as a heat conductor and connection surface.

For example, the circuit board can comprise copper or aluminum metal cores, having at least one dielectric passivation layer on the upper side and/or lower side. In particular, the circuit board can comprise a copper or aluminum plate here. The circuit board can comprise at least one dielectric passivation layer on an upper side facing toward the optoelectronic semiconductor chip or on an upper side facing toward the optoelectronic semiconductor chip and a lower side facing away. For example, the circuit board can comprise conductor tracks and contact layers on at least one dielectric passivation layer. The at least one dielectric passivation layer is arranged between the conductor tracks/contact layers and the metal core. The dielectric passivation layer can comprise FR4, aluminum oxide, aluminum nitride, silicon oxide, or silicon nitride.

Furthermore, the circuit board can comprise a ceramic circuit board having at least one exposed area having metal. In particular, the at least one exposed area having metal can function as electrical or thermal contact surfaces. The at least one exposed area having metal can provide a via extending through the ceramic circuit board or a contact layer arranged on the circuit board. In particular, the at least one baseplate of the optoelectronic semiconductor device can be thermally and/or electrically connected to the at least one exposed area having metal. Furthermore, the ceramic circuit board can comprise electrical conductor tracks on an upper side facing toward the optoelectronic semiconductor chip and/or a lower side facing away. For example, the at least one exposed area having metal can comprise copper or a copper alloy, gold or a gold alloy, silver or a silver alloy, or an alloy comprising at least two of the following materials: platinum, palladium, rhodium, ruthenium, iridium, nickel, cobalt, copper, tin, gold, or silver.

According to at least one embodiment, the optoelectronic semiconductor device comprises a circuit board which comprises at least one dielectric passivation layer, wherein the at least one passivation layer comprises contact layers and/or conductor tracks on the side facing toward and/or the side facing away from the optoelectronic semiconductor device. For example, the circuit board can comprise a metal core made of copper or aluminum, having at least one dielectric passivation layer on the upper side and/or lower side of the circuit board. The circuit board can comprise at least one dielectric passivation layer on an upper side facing toward the optoelectronic semiconductor chip or on an upper side facing toward the optoelectronic semiconductor chip and a lower side facing away. For example, the circuit board can comprise contact layers and/or conductor tracks on at least one dielectric passivation layer. The at least one dielectric passivation layer can be arranged between the contact layers and/or conductor tracks on the circuit board. The at least one dielectric passivation layer can comprise FR4, aluminum oxide, aluminum nitride, silicon oxide, or silicon nitride.

According to at least one embodiment, the optoelectronic semiconductor device comprises a first electrical contact (anode) and a second electrical contact (cathode), which are introduced from an upper side of the optoelectronic semiconductor device. In particular, the first electrical contact (anode) and the second electrical contact (cathode) are exposed on the upper side of the optoelectronic semiconductor device and extend through a molding compound arranged on the upper side of the carrier. The first electrical contact (anode) ends at a first contact pad and the second electrical contact (cathode) ends at a second contact pad on the upper side of the carrier. The first contact pad is provided electrically insulated from the second contact pad. The contact pads are formed as layers. A bond wire extends from the first electrical contact (anode) or from the first contact pad at which the first electrical contact (anode) ends to a connection layer on the upper side of the semiconductor chip. The bond wire electrically connects the optoelectronic semiconductor chip. For example, the second contact pad, at which the cathode (second electrical contact) ends, directly electrically connects the optoelectronic semiconductor chip on the lower side facing toward the carrier. Alternatively, a contact layer is arranged between the optoelectronic semiconductor chip and the carrier, which is connected via a conductor track to the second contact pad and electrically connects the optoelectronic semiconductor chip on the lower side facing toward the carrier.

According to at least one embodiment, the optoelectronic semiconductor device comprises a carrier which comprises a first electrical via for an anode and a second electrical via for a cathode. A first plurality of columns which provides the anode ends at a first via extending through the carrier and a second plurality of columns which provides the cathode ends at a second via extending through the carrier. The first electrical via contacts a first contact pad on the upper side of the carrier from below, wherein the second electrical via contacts a second contact pad on the upper side of the carrier from below. The first via and the first contact pad are provided electrically insulated from the second via and the second contact pad. The contact pads are formed as layers. Alternatively, the end faces of the vias can be exposed on the upper side of the carrier and can thus form the contact pads on the upper side of the carrier. The end faces of the vias can terminate flush with the upper side of the carrier. From the end face of the first via or from the first contact pad at which the first via ends, a bond wire extends to a connection layer on the upper side of the semiconductor chip. The bond wire electrically connects the optoelectronic semiconductor chip. For example, the second contact pad, at which the second via ends, electrically connects the optoelectronic semiconductor chip directly to the lower side facing toward the carrier. Alternatively, a contact layer is arranged between the optoelectronic semiconductor chip and the carrier, which is connected via a conductor track to the second contact pad and electrically connects the optoelectronic semiconductor chip on the lower side facing toward the carrier.

The thickness of the contact pad is preferably between 1 and 200 μm, or preferably between 10 and 100 μm, or more preferably between 25 and 75 μm. In particular, a thickness of a copper contact pad of approximately 50 μm has proven to be particularly advantageous. For example, the contact pad can comprise copper or a copper alloy, gold or a gold alloy, silver or a silver alloy, or an alloy comprising at least two of the following materials: platinum, palladium, rhodium, ruthenium, iridium, nickel, cobalt, copper, tin, gold, or silver.

In particular, the optoelectronic semiconductor device comprises a first subset of the plurality of columns, which adjoins the first electrical via, and a second subset of the plurality of columns, which adjoins the second electrical via. The first and second subset of the plurality of columns provide an electrical contact here. The first and second subset of the plurality of columns can each be soldered onto a baseplate, wherein the baseplates are provided electrically insulated from one another. In particular, the optoelectronic semiconductor device can be soldered using the at least one baseplate onto one or more contact layers of the circuit board.

According to at least one embodiment, the optoelectronic semiconductor device comprises a carrier, an optoelectronic semiconductor chip arranged on the carrier, and a column, wherein the one column is arranged on a base surface of the carrier opposite to the optoelectronic semiconductor chip and wherein the one column causes a thermal heat conduction away from the optoelectronic semiconductor chip and the carrier.

The tension which can build up in a soldered connection between two materials having different coefficients of thermal expansion is strongly dependent on the lateral dimensions of the soldered surface. For example, a full-surface metallic soldered connection between a carrier and a substrate could have the result that the tensions in the interface between the carrier and the substrate will become too high and that the soldered connection will fail as a result. For example, the problem can be solved in that the soldered surface between the carrier and the substrate is reduced. A reduced soldered surface can be created by the use of a plurality of columns or by the use of one column having a reduced base surface in relation to the carrier of the optoelectronic semiconductor device.

According to at least one embodiment, the optoelectronic semiconductor device comprises one column made of metal. The one column preferably comprises a material having good thermal conductivity. In particular, the one column can comprise copper or a copper-containing alloy. Alternatively, the one column can also comprise gold or a gold-containing alloy. The thermal conductivity of the one column can be deliberately set, for example, via the material selection. For example, the material for the one column can be selected so that it provides a certain specific thermal resistance. The thermal resistance via the one column can thus be set by the length and/or the cross-sectional area of the one column. The heat dissipation required during the operation of the optoelectronic semiconductor device from the semiconductor chip via the one column to the substrate can thus be set deliberately. The one column can have a height between 5 μm and 200 μm, or preferably a height between 10 μm and 100 μm, or particularly preferably a height between 20 μm and 60 μm. In particular, a column height of 40 μm has proven to be particularly favorable.

According to at least one embodiment, the optoelectronic semiconductor device comprises a column which has a geometric shape in cross section that is circular and/or ellipsoidal, and/or square, and/or polygonal, in particular triangular, quadrangular, pentagonal, hexagonal, or octagonal.

According to at least one embodiment, the one column covers at least 10% of the base surface of the carrier. For example, the one column covers the base surface of the carrier by at least 10% and at most 30%. In particular, efficient heat dissipation away from the carrier can thus be ensured. In general, a larger base area of the one column, at equal height, has the effect that more heat can be dissipated through the one column in the direction of the substrate. For example, the lateral dimensions of the one column exceed the lateral dimensions of the semiconductor chip arranged on the carrier by at most 500%, or preferably at most 200%, or more preferably at most 50%. Efficient heat dissipation from the semiconductor chip is in particular ensured with larger and larger lateral dimensions of the one column. The lateral dimensions of the one column can also approximately correspond to the lateral dimensions of the semiconductor chip arranged on the carrier. The lateral dimensions of the one column can also be less than the lateral dimensions of the semiconductor chip arranged on the carrier. For example, the lateral dimensions of the one column fall below the lateral dimensions of the semiconductor chip arranged on the carrier by at most 20%, or preferably at most 30%, or more preferably at most 50%.

The one column is advantageously arranged directly below the semiconductor chip on the base surface of the carrier opposite to the semiconductor chip. For example, a center point of the one column deviates from a center point of the optoelectronic semiconductor chip by at most 500 μm, or preferably at most 100 μm, or more preferably at most 20 μm. In particular, efficient heat dissipation away from the semiconductor chip can thus be ensured.

According to at least one embodiment, the one column is arranged below an area of the carrier which displays a temperature elevated in relation to the remainder of the carrier, i.e., a “hotspot”. The hotspot present in the carrier can be caused by an active or passive electric element arranged on the upper side of the carrier. For example, the hotspot can be caused by an optoelectronic semiconductor chip arranged on the upper side of the carrier.

In particular, the lateral dimensions of the one column exceed the lateral dimensions of the hotspot present in the carrier by at most 500%, or preferably at most 200%, or more preferably at most 50%. The one column is advantageously arranged below the hotspot on the base surface of the carrier opposite to the semiconductor chip. For example, a center point of the one column deviates from a center point of the hotspot by at most 500 μm, or preferably at most 100 μm, or more preferably at most 20 μm. In particular, a particularly efficient heat dissipation away from the semiconductor chip can thus be ensured.

The center of the carrier of a so-called “multichip LED array” typically has an elevated temperature over the edge area in operation. Heat can advantageously be better dissipated from the center of such a “multichip LED array” by the use of a carrier having a column which is arranged on the base surface of the carrier in the center below the “multichip LED array”. In particular, the semiconductor chips from the center of the “multichip LED array” can thus be cooled more strongly than the semiconductor chips from the edge area. It can be ensured by stronger cooling of the center of the “multichip LED array” that a homogeneous temperature is generated over the entire “multichip LED array”. In particular, a homogeneous temperature over the entire “multichip LED array” has the effect that the color shift of the semiconductor chips is the same everywhere over the “multichip LED array”. It is thus possible to prevent LEDs from the center of the “multichip LED array” from having a different color than the semiconductor chips from the edge area.

According to at least one embodiment, the optoelectronic semiconductor device comprises a carrier having a column which comprises an end cap made of solder. In particular, the carrier having the one column is fastened using the end cap on a substrate. The one column has an end face facing away from the base surface of the carrier, and at least one laterally circumferential lateral surface, which is aligned perpendicular to the end face. The end cap covers the end face and at least partially the at least one laterally circumferential lateral surface with the solder. For example, the material bond between the one column and the substrate may be created in a particularly mechanically stable manner if the end cap covers both the end face and at least partially the at least one laterally circumferential lateral surface with the solder. The thickness of the end cap is preferably between 500 nm and 10 μm, or preferably between 1 and 6 μm, or more preferably between 2 and 4 μm. In particular, a thickness of approximately 3 μm has proven to be particularly advantageous.

The substrate is preferably either a heat sink or a baseplate. If the substrate is provided as a baseplate, the baseplate can be soldered onto a heat sink or a circuit board using a solder layer on the lower side of the baseplate. In particular, the optoelectronic semiconductor device thus comprises a solder layer between the baseplate and the heat sink or the circuit board.

According to at least one embodiment, the optoelectronic semiconductor device comprises a polymer between the carrier and the substrate. The polymer can fix and/or mechanically support the carrier having the one column on the substrate. Fixing means here that the polymer provides a material adhesion between the carrier and the substrate in addition to the soldered connection between the one column and the substrate. For example, the polymer functions here as an adhesive to fasten the carrier having the one column on the substrate. In particular, the polymer between the carrier and the substrate has the effect that the optoelectronic semiconductor device is seated in a more mechanically stable manner on the substrate. For example, the polymer stabilizes the optoelectronic semiconductor device in that it functions as a space holder on all sides around the one column. In particular, the polymer has the effect here that vertical or lateral force strains on the optoelectronic semiconductor device only have a minor influence on the soldered connection between the one column and the substrate.

According to at least one embodiment, the optoelectronic semiconductor device comprises a carrier having the one column, wherein the optoelectronic semiconductor device is fastened using a polymer on a substrate. The polymer is arranged between the base surface of the carrier and the upper side of the substrate, and between the end face of the one column and the upper side of the substrate.

The polymer is preferably in direct contact with the base surface of the carrier, the upper side of the substrate, the end face of the one column, and with the at least one lateral surface of the one column. A direct contact has the effect here that a particularly reliable and mechanically stable material bond can be ensured. The polymer preferably wets the base surface of the carrier, the upper side of the substrate, and the at least one lateral surface of the one column comprehensively. In particular, the polymer wets the base surface of the carrier comprehensively only where the one column is not arranged on the base side of the carrier. The polymer wets the base surface of the carrier, the upper side of the substrate, and the at least one lateral surface of the one column by at least 50%, or preferably at least 75%, or more preferably at least 95%.

In particular, an adhesive layer is formed between the end face of the one column and the substrate. The polymer layer between the end face of the one column and the upper side of the substrate is preferably as thin as possible to ensure a low thermal resistance between the end face of the one column and the substrate. The thickness of the polymer layer between the end face of the one column and the upper side of the substrate is at most 5 μm, or preferably at most 3 μm, or more preferably at most 1 μm. The polymer layer covers the end face of the one column by at least 20%, preferably by at least 50%, more preferably by at least 75%.

For example, a high surface coverage of the polymer has the effect that a stable and reliable material bond can be ensured. Furthermore, a high surface coverage of the polymer also contributes to improved heat conduction. In particular, the good surface coverage of the polymer with the at least one lateral surface of the one column has the effect in case of a partial delamination between the end face of the one column and the substrate that good adhesion and heat conduction to the substrate can always be ensured.

In particular, the polymer is an adhesive. For example, the adhesive is based on silicone or epoxy resin. The one column has the effect here that an improved heat conduction is caused in the adhesive bond between the carrier and the substrate. The increased heat conduction is to be attributed to the one column, which is used to guide the heat through the adhesive in the direction of the substrate.

According to at least one embodiment, the optoelectronic semiconductor device comprises an anode (first contact) and a cathode (second contact), which are introduced from an upper side of the optoelectronic semiconductor device. In particular, the anode (first contact) and cathode (second contact) are exposed on the upper side of the optoelectronic semiconductor device and extend through a molding compound arranged on an upper side of the carrier. The anode (first contact) ends at a first contact pad and the cathode (second contact) ends at a second contact pad on the upper side of the carrier, wherein the first contact pad is provided electrically insulated from the second contact pad. The anode (first contact) ends at a first contact pad and the cathode (second contact) ends at a second contact pad on the upper side of the carrier, wherein the first contact pad is provided electrically insulated from the second contact pad. The contact pads are formed as layers. From the anode (first contact) or from the first contact pad at which the anode (first contact) ends, a bond wire extends to a connection layer on the upper side of the semiconductor chip. The bond wire electrically connects the optoelectronic semiconductor chip here. For example, the second contact pad, at which the cathode (second contact) ends, electrically connects the optoelectronic semiconductor chip directly to the lower side facing toward the carrier. Alternatively, a contact layer is arranged between the optoelectronic semiconductor chip and the carrier, which is connected via a conductor track to the second contact pad and electrically connects the optoelectronic semiconductor chip on the lower side facing toward the carrier.

According to at least one embodiment, an optoelectronic component comprises at least one optoelectronic semiconductor device and at least one substrate. The optoelectronic semiconductor device is arranged on the upper side of the at least one substrate. The optoelectronic semiconductor device can comprise at least one column on the base surface of the carrier. For example, the optoelectronic semiconductor device having the at least one column can be adhesively bonded or soldered on the at least one substrate. The at least one substrate can be a baseplate, heat sink, or circuit board. Furthermore, the at least one substrate can be arranged on the upper side of a further substrate. The further substrate can also be a baseplate, heat sink, or circuit board. The at least one substrate can either be adhesively bonded or soldered on the further substrate.

Furthermore, a method for producing an optoelectronic semiconductor device is specified. The optoelectronic semiconductor device described here can in particular be produced by such a method. That is to say, all features disclosed for the optoelectronic semiconductor device are also disclosed for the method and vice versa.

According to at least one embodiment of the method, an optoelectronic semiconductor device is produced using the following steps:
a) providing a carrier;
b) applying a photoresist to the base surface of the carrier;
c) structuring the photoresist using photolithography;
d) exposing the base surface of the carrier by removing an exposed or unexposed area of the photoresist;
e) galvanically growing a plurality of columns on the base surface of the carrier in the exposed areas of the photoresist;
f) removing the photoresist;
g) providing at least one optoelectronic semiconductor chip arranged on the carrier;
h) isolating the carrier;
i) fastening the optoelectronic semiconductor device on a substrate.

According to at least one embodiment of the method, in step a), a seed layer is applied over the full surface on the base surface of the carrier. The seed layer enables the plurality of columns in step e) to be able to be applied using galvanic growth to the base surface of the carrier. The seed layer which is present between the plurality of columns can be chemically etched away again after the plurality of columns are grown. Alternatively, the seed layer can first be applied after step d). The exposed areas of the base surface of the carrier and the photoresist are coated using the seed layer. Subsequent etching can thus advantageously be dispensed with in that no seed layer is present between the plurality of columns on the base surface of the carrier after the removal of the photoresist.

For example, the seed layer can be produced using sputtering or physical gas phase deposition. In particular copper or titanium are used as seed layers. The seed layer has a thickness between 10 nm and 1 μm, preferably between 50 nm and 500 nm, more preferably between 150 nm and 250 nm. In particular, a thickness of the seed layer of 200 nm has proven to be particularly stable in order to galvanically grow the plurality of columns.

According to at least one embodiment of the method, an optoelectronic semiconductor device in step i) is fastened using a polymer on an upper side of a substrate, wherein the substrate is a circuit board. For example, the optoelectronic semiconductor device having the carrier comprising a plurality of columns can be placed with the base side of the carrier facing away from the semiconductor chip in a liquid polymer droplet arranged on the circuit board. Excess polymer material is pressed out laterally, so that the polymer can laterally overflow the base surface of the carrier. Furthermore, the excess polymer which laterally overflows the base surface of the carrier can slightly rise up the carrier end side. The expression “slightly” in this context means that the polymer rises up at least 10% of the height of the carrier end side, or at least 30%, or at least 50%. For example, an adhesive bond which is larger in area and is thus particularly reliable may thus be created between the carrier and the substrate. For example, the polymer droplet can comprise a silicone or epoxy-based adhesive. The polymer droplet can be arranged, for example, jetting, dispensing, casting, molding, or offset printing on the carrier. Multiple droplets can preferably be arranged simultaneously on the carrier. For example, multiple optoelectronic semiconductor devices can thus be placed simultaneously in a batch method in the polymer droplet arranged on the substrate. The liquid polymer is cured subsequently to the arrangement of the optoelectronic semiconductor device, wherein the polymer fixes the optoelectronic semiconductor device on the substrate.

According to at least one embodiment of the method, the plurality of columns in step e) are each provided with a AuSn end cap. The AuSn end caps can advantageously be applied to the plurality of columns using galvanic growth in step e).

The thickness of the end caps is preferably between 500 nm and 10 μm, or preferably between 1 and 6 μm, or more preferably between 2 and 4 μm. In particular, a thickness of 3 μm has proven to be particularly advantageous in that a stable soldered connection can be ensured with low material use.

According to at least one embodiment of the method, the optoelectronic semiconductor device is soldered in step i) using the AuSn end caps on the upper side of a substrate, wherein the substrate is a circuit board or heat sink. For example, the optoelectronic semiconductor device comprising the carrier having the plurality of columns can be fastened on the substrate using reflow soldering. Alternatively, the optoelectronic semiconductor device can be pressed down on the substrate with the end caps facing toward the upper side of the substrate, wherein the substrate is heated on a lower side of the substrate opposite to the upper side of the substrate.

According to at least one embodiment of the method, in step i) a polymer is arranged around the optoelectronic semiconductor device on the substrate, wherein the polymer soaks in between the base surface of the carrier and the upper side of the substrate and between the plurality of columns. For example, the liquid polymer is applied to the substrate directly adjoining the outer columns soldered onto the substrate. The polymer can be applied to the substrate over the entire periphery on all sides around the optoelectronic semiconductor device, or can be arranged only on one, two, or three sides around the optoelectronic semiconductor device. When the polymer is arranged on the substrate, the liquid polymer laterally directly adjoins the outermost rows of the plurality of columns. The liquid polymer thus preferably soaks in between the plurality of columns and the carrier and the substrate due to the capillary forces acting on the polymer. The polymer thus preferably fills the entire volume between the carrier and the substrate, and between the plurality of columns. A polymer without filler material is preferably used for this, which can soak in more easily between the plurality of columns. The polymer is subsequently cured, wherein the polymer mechanically supports the plurality of columns in the cured state.

According to at least one embodiment of the method, the optoelectronic semiconductor device is soldered in step i) using the AuSn end caps on the upper side of the substrate, wherein the substrate comprises at least one baseplate.

According to at least one embodiment of the method, the lower side of the at least one baseplate is coated using a solder layer, wherein the optoelectronic semiconductor device is fastened using the solder layer on a circuit board or a heat sink.

According to at least one embodiment of the method, a polymer is provided between the plurality of columns, wherein the AuSn end caps (X) are exposed from the polymer.

According to at least one embodiment of the method, the polymer is provided between the plurality of columns by foil-assisted injection molding (foil-assisted molding), dispensing, squeegeeing, casting, or molding. For example, the polymer is infiltrated between the plurality of columns and thus completely wets the base surface of the carrier where the plurality of columns are not arranged on the carrier. The polymer completely surrounds the lateral surfaces of the plurality of columns here. For example, the polymer can be applied from the base surface of the carrier to the end faces of the plurality of columns, wherein the end faces of the plurality of columns are provided free of the polymer. A smooth polymer surface thus results, which is only interrupted by the end faces of the plurality of columns. Alternatively, the polymer also completely covers the end faces of the plurality of columns and thus forms an uninterrupted polymer surface which protrudes beyond the end faces of the plurality of columns in the direction facing away from the base surface of the carrier. In a following step, the polymer, starting from the polymer surface and in the direction of the base surface of the carrier, is ground down and/or plasma-cleaned to the depth required for the end caps. In a following step, the plurality of columns is provided with end caps using galvanic deposition. The end caps cover the exposed end faces and the exposed lateral surfaces of the plurality of columns here. Alternatively, the plurality of columns can be pressed into a polymer film up to a depth required for the end caps. In a following step, the columns are infiltrated by a liquid polymer, wherein the polymer extends from the base surface of the carrier to the polymer film. In a following step, the polymer film is removed. In particular, in this way the end faces and fractionally also the lateral surfaces of the plurality of columns are provided exposed from the polymer. For example, a subsequent grinding and/or plasma cleaning process can thus be omitted in order to expose the end faces and the lateral surfaces of the plurality of columns from the polymer. In a following step, the end caps can be applied using galvanic deposition to the exposed end faces and the exposed lateral surfaces of the plurality of columns.

According to at least one embodiment of the method, the polymer is provided between the plurality of columns by foil-assisted injection molding (foil-assisted molding), dispensing, squeegeeing, casting, or molding. The plurality of columns are already provided with end caps made of AuSn solder before the intermediate spaces of the plurality of columns are infiltrated using a polymer. The end caps are applied subsequently to step e) using galvanic deposition to the end faces and the lateral surfaces of the plurality of columns. In particular, the photoresist between the plurality of columns is first etched down in the direction of the base surface of the carrier before the end caps are galvanically coated on the plurality of columns in step e).

For example, a polymer is infiltrated between the plurality of columns and thus completely wets the base surface of the carrier where the plurality of columns are not arranged on the carrier. The polymer completely surrounds the lateral surfaces of the plurality of columns. For example, the polymer can be applied from the base surface of the carrier to the base surfaces of the end caps. A smooth polymer surface thus results, which is only interrupted by the base surfaces of the end caps. Alternatively, the polymer also completely covers the end caps of the plurality of columns and thus forms an uninterrupted polymer surface which protrudes beyond the end caps of the plurality of columns in the direction facing away from the base surface of the carrier. In a following step, the polymer can be ground down and/or plasma-cleaned, starting from the polymer surface and in the direction of the base surface of the carrier, to the depth required for the end caps. That is to say, the end caps of the plurality of columns are completely exposed by the grinding process and/or plasma cleaning process.

Alternatively, the plurality of columns having the end caps can be pressed into a film, wherein the columns are pressed in to a depth corresponding to the height of the end caps. In a following step, the columns are infiltrated by the polymer, wherein the polymer extends from the base surface of the carrier to the film and the end caps. In a following step, the film is removed. In particular, in this way the end caps are provided exposed from the polymer. For example, a subsequent grinding and/or plasma cleaning process can thus be omitted.

According to at least one embodiment of the method, the optoelectronic semiconductor device is soldered in step i) using the AuSn end caps exposed from the polymer on the plurality of columns onto the upper side of the substrate, wherein the substrate comprises at least one baseplate.

According to at least one embodiment of the method, the lower side of the at least one baseplate is coated using a solder layer, wherein the optoelectronic semiconductor device is fastened using the solder layer on a circuit board or heat sink.

According to at least one embodiment of the method, the solder layer comprises an alloy which comprises at least two of the following elements: Ag, Al, Au, Bi, Cd, Cu, Fe, P, Pb, Sb, Si, Sn, Zn. An AuSn-based or SnAgCu-based solder can advantageously be used.

According to at least one embodiment of the method, the carrier of the optoelectronic semiconductor device comprises a plurality of columns in step h) after the isolation of the carrier.

According to at least one embodiment of the method, the carrier of the optoelectronic semiconductor device comprises one column in step h) after the isolation of the carrier.

According to at least one embodiment of the method, only one column is arranged on the carrier of the optoelectronic semiconductor device in step h). For example, the carrier comprising a plurality of columns can be isolated in step h), so that a new carrier comprising only one column on the base surface is formed.

According to at least one embodiment of the method, the at least one baseplate is provided in a structured or isolated form. For example, the at least one baseplate can comprise one or more pre-structured parts. Alternatively, the at least one baseplate can be structured or isolated only after the connection to the plurality of columns. For example, the at least one baseplate, consisting of a pre-structured part or consisting of multiple pre-structured parts, can be provided as such. Alternatively, the at least one baseplate can first be structured after the connection to the plurality of columns. The at least one baseplate is provided in a first step as a substrate in the form of a film, plate, block, or layer. For example, the carrier comprising the plurality of columns can be fastened on the substrate using the end caps. In a following step, the substrate is structured or isolated. For example, the substrate can be structured or isolated using a chemical or mechanical method. A photolithography process with a subsequent etching process is suitable in particular as a chemical structuring method. The lower side of the substrate is coated over the entire surface with a photoresist and the photoresist is subsequently exposed through a photomask. In a following step, the exposed or unexposed areas of the photoresist are removed, for example, by a washing process. In a following step, the exposed areas of the baseplate are etched. For example, the substrate can be slightly etched, wherein material is removed from the lower side of the substrate to create a depression in the lower side of the substrate. Alternatively, the substrate can be etched through completely so that at least one structured baseplate comprising multiple parts is created. Furthermore, as an alternative thereto or in combination with the chemical separating method, the following material-removing structuring methods suggest themselves to provide the at least one baseplate: laser cutting, sawing, drilling, milling, or water jet cutting.

According to at least one embodiment of the method, the at least one baseplate is galvanically grown. For example, the polymer is up to the end faces of the plurality of columns here. In particular, a polymer surface interrupted by the end faces of the plurality of columns is thus provided. In a following step, a seed layer made of copper or titanium is then applied to the polymer surface interrupted by the end faces of the plurality of columns. For example, a baseplate is galvanically grown on the seed layer. Very thin baseplates can thus advantageously be provided. In particular, baseplates in the form of layers in the micrometer range can thus be provided.

For example, the baseplate can be coated using a photoresist. In particular, the photoresist is structured in a following step by photolithography, wherein the exposed or unexposed areas of the photoresist are removed. In a following step, the areas of the baseplate thus exposed are etched away, wherein at least one structured baseplate is provided.

Alternatively thereto, the polymer surface interrupted by the end faces of the plurality of columns, having the seed layer, can be coated using a photoresist. In particular, the photoresist is structured in a following step by photolithography, wherein the exposed or unexposed areas of the photoresist are removed. In a following step, the at least one baseplate is galvanically grown in the exposed areas of the photoresist on the seed layer. The photoresist is then washed away, wherein the at least one baseplate is provided.

Further advantages and advantageous embodiments and refinements of the optoelectronic semiconductor chip and the method result from the following exemplary embodiments described in conjunction with schematic drawings.

In the figures:

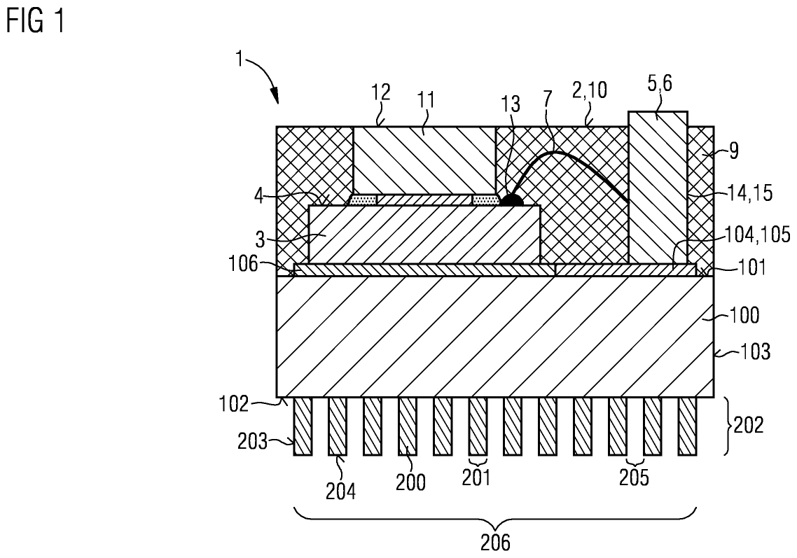

FIG. 1 shows a side view of an optoelectronic semiconductor device according to an exemplary embodiment,

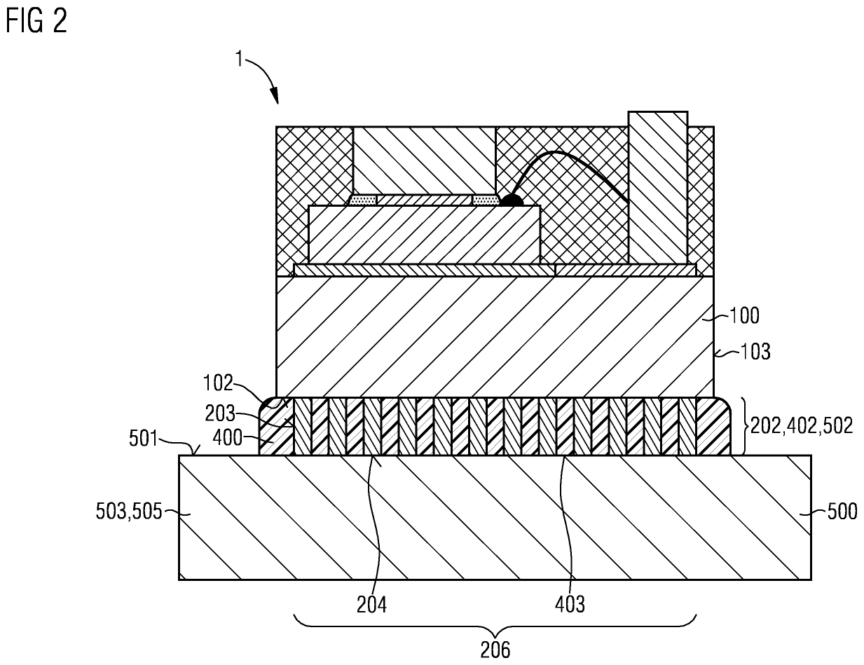

FIG. 2 shows a side view of an optoelectronic semiconductor device having a substrate according to an exemplary embodiment,

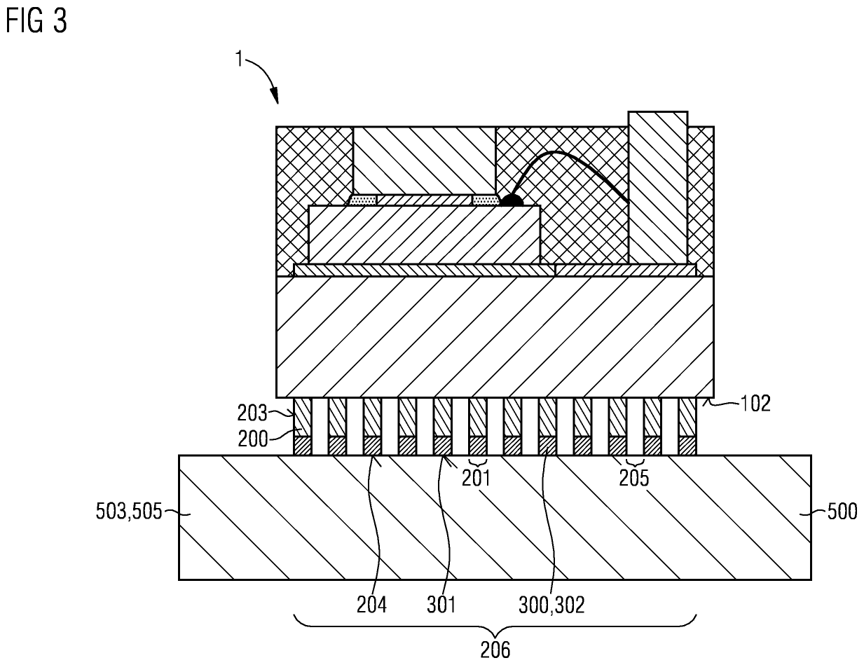

FIG. 3 shows a side view of an optoelectronic semiconductor device having a substrate according to an exemplary embodiment,

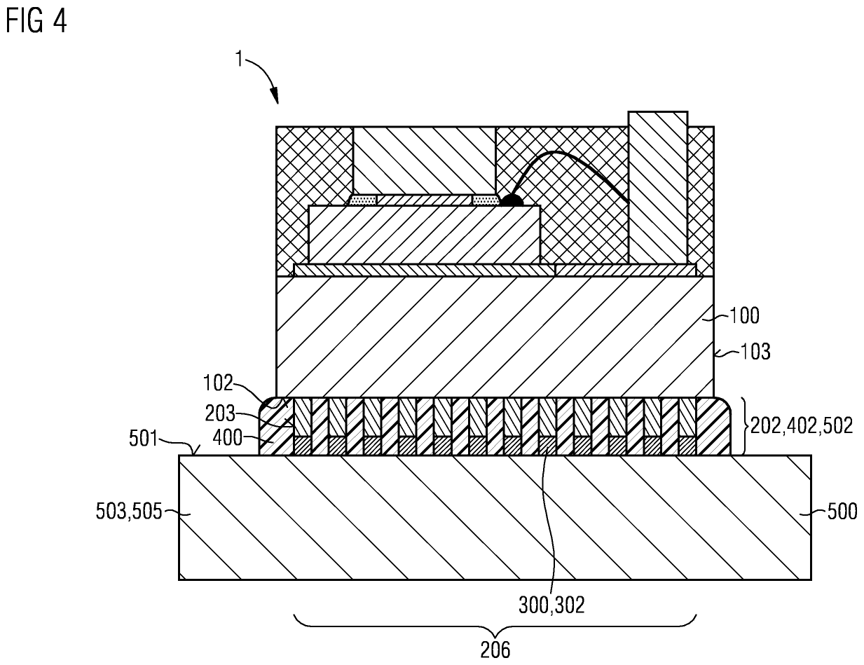

FIG. 4 shows a side view of an optoelectronic semiconductor device having a substrate according to an exemplary embodiment,

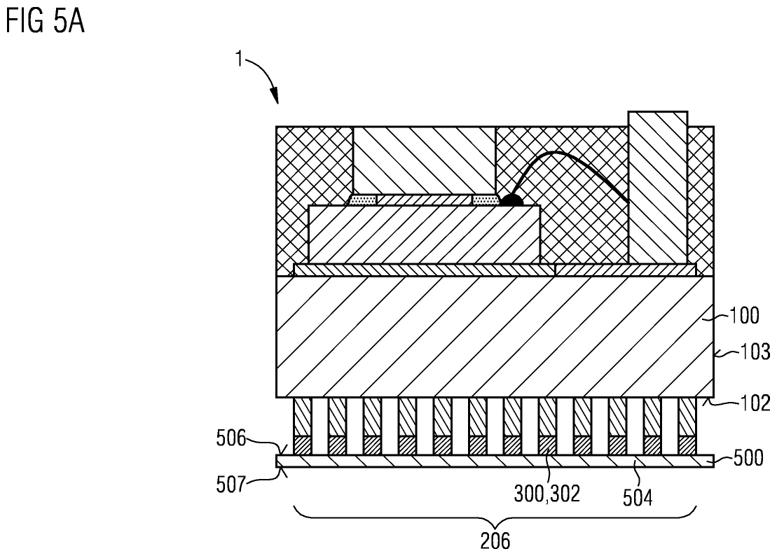

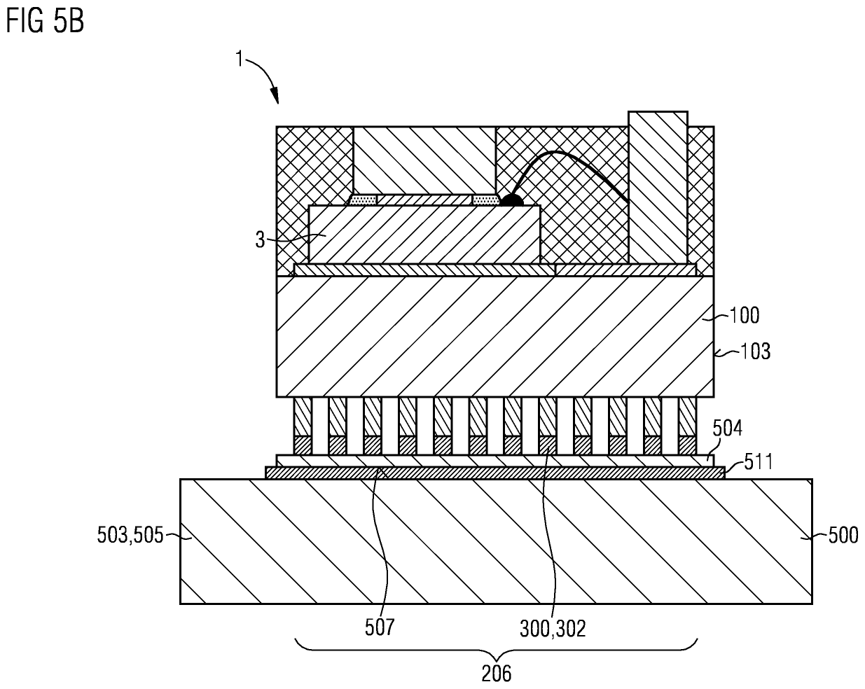

FIG. 5A shows a side view of an optoelectronic semiconductor device having at least one baseplate according to an exemplary embodiment,

FIG. 5B shows a side view of an optoelectronic semiconductor device having at least one baseplate and a substrate according to an exemplary embodiment,

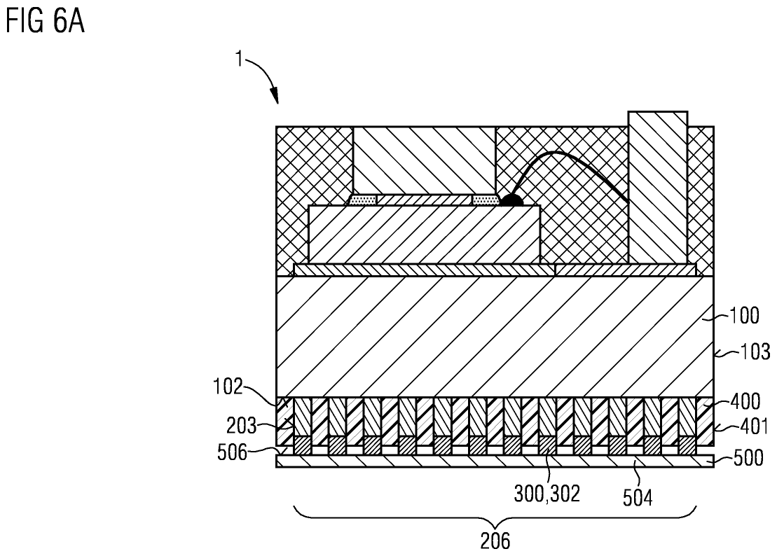

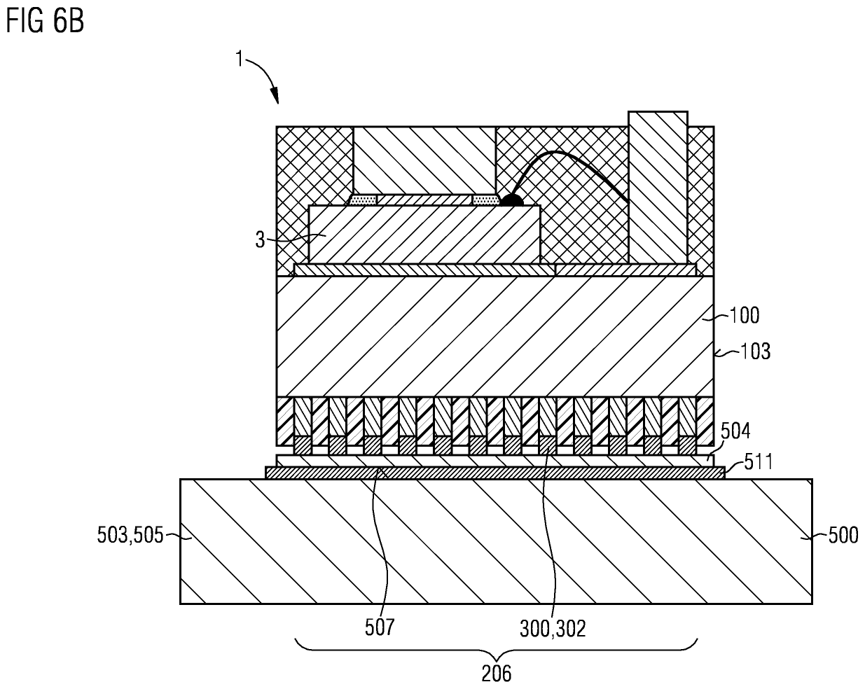

FIG. 6A shows a side view of an optoelectronic semiconductor device having at least one baseplate according to an exemplary embodiment,

FIG. 6B shows a side view of an optoelectronic semiconductor device having at least one baseplate and a substrate according to one exemplary embodiment,

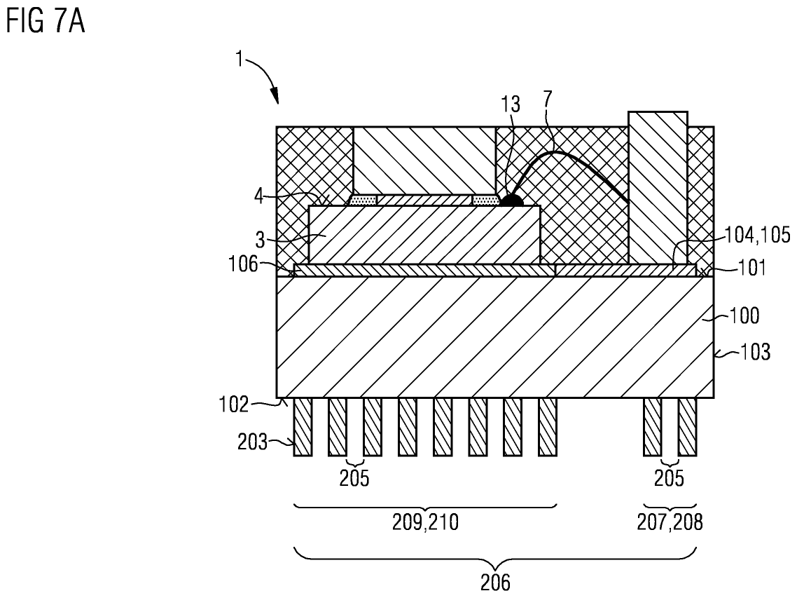

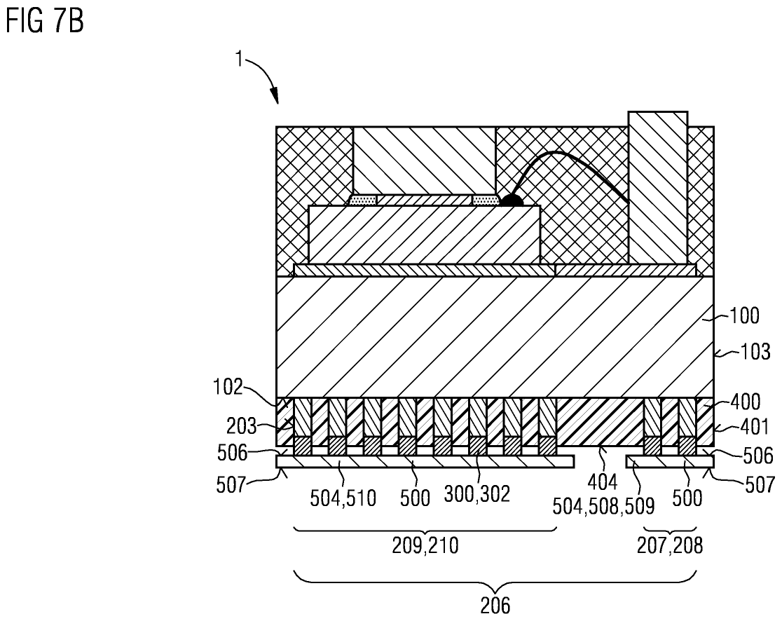

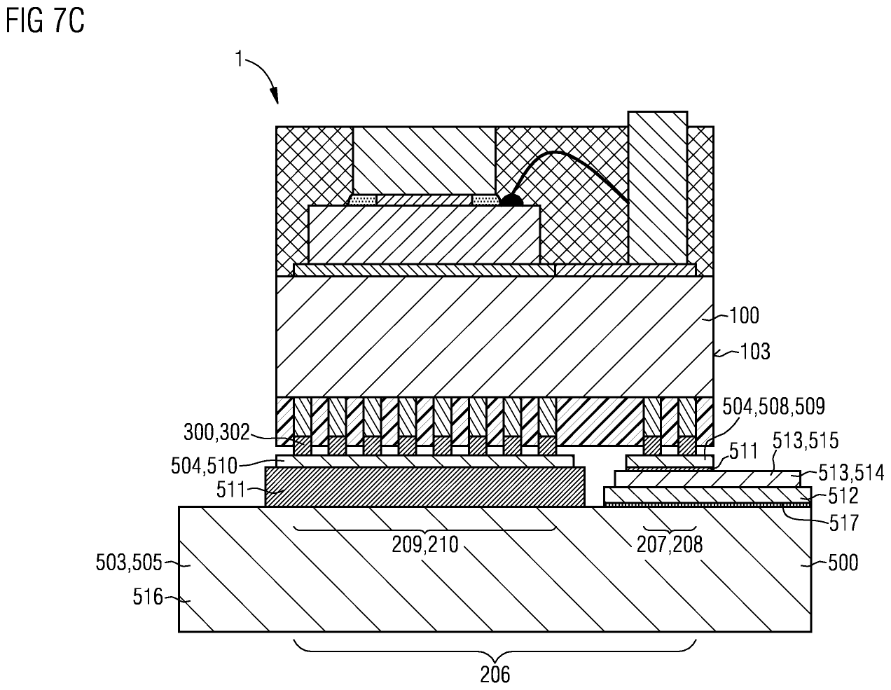

FIG. 7A shows a side view of an optoelectronic semiconductor device according to an exemplary embodiment,

FIG. 7B shows a side view of an optoelectronic semiconductor device having at least one baseplate according to an exemplary embodiment,

FIG. 7C shows a side view of an optoelectronic semiconductor device having at least one baseplate and a substrate according to an exemplary embodiment,

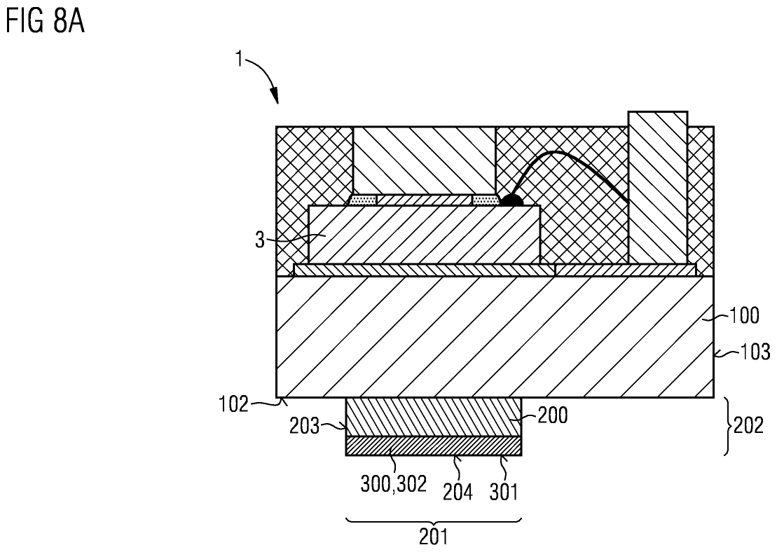

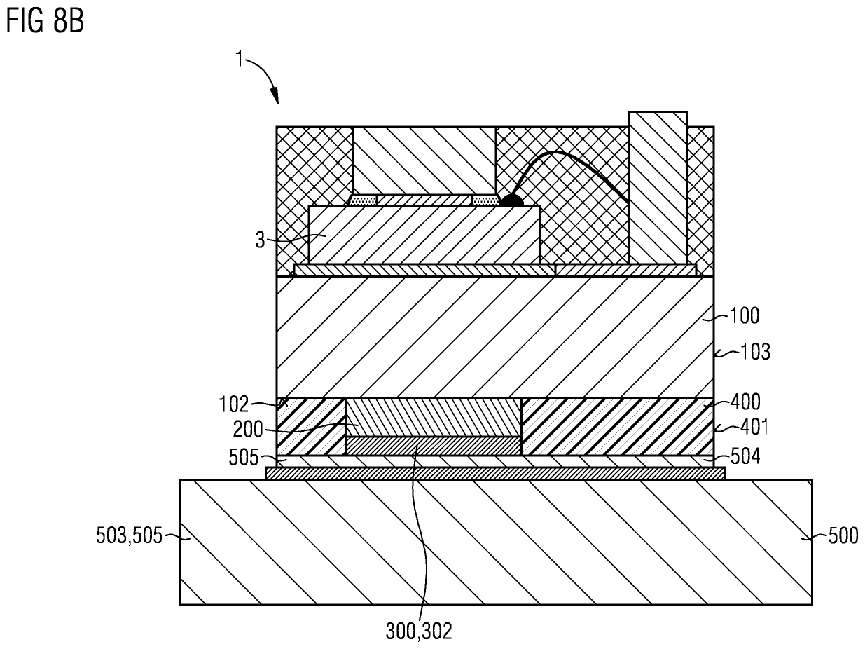

FIG. 8A shows a side view of an optoelectronic semiconductor device according to an exemplary embodiment,

FIG. 8B shows a side view of an optoelectronic semiconductor device having a substrate according to an exemplary embodiment.

Identical, similar, or identically acting elements are provided with identical reference signs in the figures. The figures and the size relationships of the elements shown in the figures among one another are not considered to be to scale. Rather, individual elements can be shown exaggeratedly large for better illustration and/or for better comprehension.

The optoelectronic semiconductor device 1 according to the exemplary embodiment of FIG. 1 comprises a carrier 100, an optoelectronic semiconductor chip 3 arranged on the carrier 100, and a plurality of columns 206, wherein the plurality of columns 206 are arranged on a base surface of the carrier 102 opposite to the optoelectronic semiconductor chip 3. The plurality of columns 206 promote thermal heat conduction away from the optoelectronic semiconductor chip 3 and the carrier 100. The plurality of columns 206 are arranged equidistantly from one another on the base surface of the carrier 102, i.e., the plurality of columns 206 have the same column distance 205. The lateral surfaces 203 of the plurality of columns 206 are arranged perpendicular to the base surface of the carrier 102 and extend parallel to one another toward the carrier 100. The end faces 204 of the plurality of columns 206 end at the same distance in the direction away from the carrier 100.

An optical element 11 is arranged on the upper side of the optoelectronic semiconductor chip 4 facing away from the upper side of the carrier 101. An adhesive is arranged between the optical element 11 and the optoelectronic semiconductor chip 3. The adhesive can be a silicone, for example. For example, the optical element 11 can comprise one or more luminescent phosphors, which are mixed in a matrix made of silicone. Alternatively, the optical element can consist of ceramic, wherein the ceramic comprises at least one luminescent phosphor. The optical element 11 converts a primary radiation emitted by the optoelectronic semiconductor chip 3 into a secondary radiation emitted by the optical element 11. The peak wavelength of the secondary radiation has a longer wavelength than the peak wavelength of the primary radiation. The primary radiation and the secondary radiation form a mixed light emitted by the optoelectronic semiconductor device 1.

A molding compound 9 completely surrounds the optoelectronic semiconductor chip 3 and the optical element 11. The molding compound 9 terminates flush with the carrier end side 103 and with an upper side of the optical element 12. For example, the molding compound 9 comprises a thermoplastic. The thermoplastic can comprise polyphthalamide (PPA) or polychlorinated terphenyls (PCT). The molding compound can preferably comprise light reflecting fillers such as titanium oxide.

The optoelectronic semiconductor device 1 furthermore comprises a first electrical contact 5 that functions as an anode and a second electrical contact 6 that functions as a cathode. The first electrical contact 5 and the second electrical contact 6 are aligned perpendicular to the upper side of the carrier 101 and extend parallel to one another in the direction of the upper side of the carrier 101. The first electrical contact 5 and the second electrical contact 6 are provided electrically insulated from one another here. In particular, the molding compound 9 is arranged between the first electrical contact 5 and the second electrical contact 6. The molding compound 9 completely encloses the walls (14, 15) of the first electrical contact 5 and the second electrical contact 6 extending perpendicular to the upper side of the carrier 101. The first electrical contact 5 and the second electrical contact 6 are exposed on an upper side of the molding compound 10 facing away from the upper side of the carrier 101. In particular, the first electrical contact and the second electrical contact can be individually contacted on an upper side of the optoelectronic semiconductor device 2 facing away from the upper side of the carrier 101. The first electrical contact 5 and the second electrical contact 6 can protrude beyond the upper side of the molding compound 10 in the vertical direction away from the carrier 100. If the two contacts protrude beyond the molding compound 9 in the vertical direction away from the upper side of the carrier 101, an individual electrical contact is implementable more easily.

The first electrical contact 5 and the second electrical contact 6 extend perpendicularly to the upper side of the carrier 101 through the molding compound 9. The first electrical contact 5 ends at a first contact pad 104 and the second electrical contact 6 ends at a second contact pad 105 on the upper side of the carrier 100. The first contact pad 104 is provided electrically insulated from the second contact pad 105. From the first electrical contact 5 or from the contact pad 104, at which the first electrical contact 5 ends, a bond wire 7 extends to a connection layer 13 on the upper side of the semiconductor chip 4. The contact pad 105 of the second electrical contact 6 electrically connects the optoelectronic semiconductor chip 3 on a lower side facing toward the carrier 100. Alternatively, the contact pad 6 electrically connects a contact layer 106 arranged between the optoelectronic semiconductor chip 3 and the carrier 100 via a conductor track.

The optoelectronic semiconductor device 1 according to the exemplary embodiment of FIG. 2 differs from the exemplary embodiment of FIG. 1 in that the optoelectronic semiconductor device 1 is fastened using a polymer 400 on the upper side of a substrate 500. The optoelectronic semiconductor device 1 according to FIG. 2 comprises a polymer 400, which is provided between the plurality of columns 206. The polymer 400 is present in particular between the base surface of the carrier 102, where the plurality of columns 206 are not arranged, and the upper side of the substrate 501. Furthermore, the polymer 400 is present as a polymer layer 403 between the end faces 204 of the plurality of columns 206 and the upper side of the substrate 501. The polymer 400 is in direct contact here with the base surface of the carrier 102, the lateral surfaces 203 of the plurality of columns 206, the upper side of the substrate 501, and with the end faces 203 of the plurality of columns 206. The direct contact of the polymer 400 has the effect that a particularly reliable and mechanically stable material bond and material adhesion can be ensured. In particular, the polymer 400 fixes the plurality of columns 206 on the substrate 500.

A polymer material joint 402 between the carrier 100 and the substrate 500 is determined in particular by the height of the plurality of columns (202, 206). For example, a polymer material joint 402 may thus be implemented which reproducibly has the same height everywhere between a base surface of the carrier 102 and an upper side of a substrate 501. The polymer 400 can laterally overflow the base surface of the carrier 102. Excess polymer 400 which laterally overflows the base surface of the carrier 102 can furthermore rise up and join the carrier end side 103. A particularly reliable adhesive bond may preferably thus be created between the carrier 100 and the substrate 500. The substrate 500 can comprise a heat sink 505, circuit board 503, or baseplate.

The optoelectronic semiconductor device 1 according to the exemplary embodiment of FIG. 3 differs from the exemplary embodiment of FIG. 1 in that the optoelectronic semiconductor device 1 is fastened using end caps 300 made of solder 302 onto the upper side of a substrate 500. The optoelectronic semiconductor device 1 comprises a plurality of columns 206, which each comprise an end cap 300, wherein the optoelectronic semiconductor device 1 is soldered using the end caps 300 on the substrate 500. The substrate 500 can comprise a heat sink 505, circuit board 503, or at least one baseplate 504.

The plurality of columns 206 each have an end face 204 facing away from the base surface of the carrier 102, and at least one laterally circumferential lateral surface 203, which is aligned perpendicular to the end face 204. The end caps 300 of the plurality of columns 206 cover the end face 204 of each column and at least partially the at least one laterally circumferential lateral surface of a column 203 with solder 302. For example, the material bond between the plurality of columns 206 and the substrate 500 may be created in a particularly mechanically stable manner if the end caps 300 cover both the end faces 204 and at least partially the at least one laterally circumferential lateral surface 203 with the solder 302. The end caps 300 at least partially covering the at least one lateral surface of a column 203 has the effect that an increased connection area can be created for the soldered connection between the plurality of columns 206 and the substrate 500. The solder 302 in the soldered connection covers the end faces 204 of the plurality of columns 206, at least partially covers the at least one lateral surface of a column 203, and covers the substrate 500 under the plurality of columns 206. The solder 302 covers the end faces 204 of the plurality of columns 206 and less than half the column distance 205 around a column 200 of the plurality of columns 206. An interrupted solder surface is thus created which has a lower thermal tension than a full surface solder layer.

The optoelectronic semiconductor device 1 according to the exemplary embodiment of FIG. 4 differs from the exemplary embodiment of FIG. 3 in that a polymer 400 is present in the intermediate spaces of the plurality of columns 206. For example, the polymer 400, in addition to the end caps 300 made of solder 302, contributes to the adhesion in the connection between the carrier 100 having the plurality of columns 206 and the substrate 500. The polymer 400 increases the mechanical stability of the plurality of columns 206 and/or of the soldered connections between the end caps 300 and the substrate 500.

The optoelectronic semiconductor device 1 comprises a polymer 400 which is arranged between the plurality of columns 206. The polymer 400 preferably fills the entire volume between the plurality of columns 206 and between the carrier 100 and the substrate 500. The polymer 400 is arranged in particular between the base surface of the carrier 102, where the plurality of columns 206 are not arranged, and the upper side of the substrate 501. The polymer 400 is in direct contact with the base surface of the carrier 102, the lateral surfaces 203 of the plurality of columns 206, the upper side of the substrate 501, and the end caps 300 made of solder 302. The direct contact of the polymer 400 has the effect that a particularly reliable and mechanically stable material bond and material adhesion can be ensured. In particular, the polymer 400 fixes the plurality of columns 206 on the substrate 500. A polymer material joint 402 between the carrier 100 and the substrate 500 is in particular defined by the height 202 of the plurality of columns 206. For example, a polymer material joint 402 may thus be implemented which has the same height reproducibly everywhere between a base surface of the carrier 102 and an upper side of a substrate 501. The polymer 400 can laterally overflow the base surface of the carrier 102. Excess polymer 400 which laterally overflows the base surface of the carrier 102 can furthermore rise up and join the carrier end face 103. Preferably, a particularly reliable adhesive bond may thus be created between the carrier 100 and the substrate 500. The substrate 500 can comprise a heat sink 505, circuit board 503, or at least one baseplate 504.

The exemplary embodiment shown in FIG. 5A essentially corresponds to the exemplary embodiment described in conjunction with FIG. 3. In contrast thereto, the optoelectronic semiconductor device 1 comprises a baseplate 504 as the substrate 500. The plurality of columns 206 are soldered using the end caps 300 made of solder 302 onto the upper side 506 of the baseplate 504. The baseplate 504 can terminate flush with the carrier end side 103. Alternatively, the baseplate 504 can protrude beyond the carrier end side 103 in the lateral direction. The baseplate 504 can have a shape and an area which corresponds to the shape or the area occupied by the plurality of columns 206 arranged on the base surface of the carrier 102. The baseplate 504 can have a shape which corresponds to an outer contour of the plurality of columns 206. In particular, the baseplate 504 has the same geometric shape as the carrier 100.

The exemplary embodiment shown in FIG. 5B essentially corresponds to the exemplary embodiment described in conjunction with FIG. 5A. In contrast thereto, the optoelectronic semiconductor device 1 comprises a further substrate 500. The second substrate 500 can be a heat sink 505 or circuit board 503. The baseplate 504 according to the exemplary embodiment 5B comprises a solder layer 511 on a lower side 507 facing away from the optoelectronic semiconductor chip 3. The optoelectronic semiconductor device is materially bonded using the solder layer 511 on the lower side of the baseplate 507 to the heat sink 505 or the circuit board 503. In particular, the optoelectronic semiconductor device according to FIG. 5B comprises a solder layer 511 between the baseplate 504 and the further substrate 500. The plurality of columns 206 arranged between the carrier 100 and the baseplate 504 in particular compensate for the differences in coefficients of thermal expansion between the carrier 100 and the heat sink 505 or the circuit board 503.

The exemplary embodiment shown in FIG. 6A essentially corresponds to the exemplary embodiment described in conjunction with FIG. 5A. In contrast thereto, the optoelectronic semiconductor device 1 comprises a polymer 400 in the intermediate spaces of the plurality of columns 206 and between the carrier 100 and the baseplate 504. The polymer 400 preferably fills the entire volume between the plurality of columns 206 and between the carrier 100 and the baseplate 504. The polymer 400 is arranged in particular between the base surface of the carrier 102, where the plurality of columns 206 are not arranged, and the upper side of the baseplate 506. The polymer 400 is in direct contact with the base surface of the carrier 102 and the lateral surfaces 203 of the plurality of columns 206. The polymer 400 fixes the plurality of columns 206 and increases their mechanical stability in that it laterally supports the plurality of columns 206. The polymer end side 401 terminates flush with the carrier end side 103. For example, such optoelectronic semiconductor devices 1 are particularly space-saving and may be placed closer to one another and/or to other electronic components.

The exemplary embodiment shown in FIG. 6B essentially corresponds to the exemplary embodiment described in conjunction with FIG. 6A. In contrast thereto, the optoelectronic semiconductor device 1 comprises a second substrate 500. The second substrate can be a heat sink 505 or circuit board 503. The baseplate 504 according to the exemplary embodiment 6B comprises a solder layer 511 on a lower side 507 facing away from the optoelectronic semiconductor chip 3. The optoelectronic semiconductor device 1 is materially bonded using the solder layer 511 on the lower side of the baseplate 507 having the heat sink 505 or the circuit board 503. In particular, the optoelectronic semiconductor device 1 according to FIG. 6B comprises a solder layer 511 between the baseplate 504 and the further substrate 500. The plurality of columns 206 arranged between the carrier 100 and the baseplate 504 in particular compensate for the differences in coefficients of thermal expansion between the carrier 100 and the heat sink 505 or the circuit board 503.

The exemplary embodiment shown in FIG. 7A essentially corresponds to the exemplary embodiment described in conjunction with FIG. 1. In contrast thereto, the plurality of columns 206 are arranged on the carrier 100 in distinctly bounded electrically insulated subsets (207, 208, 209). For example, one or more subsets of the plurality of columns provide an electrical contact. In FIG. 7A, the plurality of columns 206 are provided in three subsets (207, 208, 209) spaced apart from one another. The columns within the subsets (207, 208, 209) of the plurality of columns 206 are arranged equidistantly from one another on the carrier 100. In particular, all of the three subsets (207, 208, 209) have the same column distances 205.

The first subset 207 of the plurality of columns 206 provides an anode and the second subset 208 of the plurality of columns 206 provides a cathode, which function as electrical feeds. A third subset 209 of the plurality of columns 206 can be present in an electrically neutral manner and can provide a thermal contact. In particular, the third subset 209 of the plurality of columns 206 is arranged on the base surface of the carrier 102, opposite to the semiconductor chip 3, directly below the semiconductor chip 3 on the carrier 100.

The optoelectronic semiconductor device 1 comprises a carrier 100, which comprises a first electrical via 107 and a second electrical via 108. The first and second via (107, 108) are not shown in FIGS. 7A to 7C. A first subset of the plurality of columns 207, which provides the anode, ends at a first electrical via 107 extending through the carrier 100, and the second subset of the plurality of columns 208, which provides the cathode, ends at a second electrical via 108 extending through the carrier 100. The first electrical via 107 contacts a first contact pad 104 on the upper side 101 of the carrier 100 from below, wherein the second electrical via 108 contacts a second contact pad 105 on the upper side of the carrier 101 from below. The first electrical via 107 and the first contact pad 104 are present in a manner electrically insulated from the second electrical via 108 and the second contact pad 105.

From the first contact pad 104, at which the first electrical via 107 ends, a bond wire 7 extends to a connection layer 13 on the upper side 4 of the optoelectronic semiconductor chip 3. The second contact pad 105 directly electrically adjoins the semiconductor chip 3 on the lower side facing toward the upper side of the carrier 101. Alternatively, the second contact pad 105 adjoins a contact layer 106, arranged between the semiconductor chip 3 and the carrier 100, via a conductor track.

The exemplary embodiment shown in FIG. 7B essentially corresponds to the exemplary embodiment described in conjunction with FIG. 7A. In contrast thereto, the optoelectronic semiconductor device according to the exemplary embodiment 7B comprises a polymer 400 and a substrate 500. The substrate 500 can comprise multiple baseplates 508, 509, 510. In particular, the first subset of the plurality of columns 207 is connected to a first baseplate 508, the second subset of the plurality of columns 208 is connected to a second baseplate 509, and the third subset of the plurality of columns 209 is connected to a third baseplate 510. The first, second, and third subset of the plurality of columns (207, 208, 209) comprise end caps 300 made of solder 302. In particular, the first subset of the plurality of columns 207 is soldered using the end caps 300 onto a first baseplate 508, the second subset of the plurality of columns 208 is soldered using the end caps 300 onto a second baseplate 509, and the third subset of the plurality of columns 209 is soldered using the end caps 300 onto a third baseplate 510.

The first, second, and third baseplate 508, 509, 510 are provided separately from one another. In particular, the first baseplate 508, the second baseplate 509, and the third baseplate 510 are present in a manner electrically insulated from one another. The first baseplate 508 and the first subset of the plurality of columns 207 provide an anode and the second baseplate 509 and the second subset of the plurality of columns 208 provide a cathode. The first baseplate 508 and the first subset of the plurality of columns 207 and the second baseplate 509 and the second subset of the plurality of columns 208 provide an electrical and thermal contact. The third baseplate 510 having the third subset of the plurality of columns 209 is present in electrically neutral manner. The third subset of the plurality of columns 209 having the third baseplate 510 provides a thermal contact.

The surface of an upper side 507 of the first baseplate 508 is at least as large as the area on the base surface of the carrier 102 required for the first subset of the plurality of columns 207. In particular, the first baseplate 508 has the same shape as the outer contour of the first subset of the plurality of columns 207. For example, the outer contours of the first subset of the plurality of columns 207 assume the shape of a square, the upper side 506 of the first baseplate 508 is then also square. This also applies to the second baseplate 509 connected to the second subset of the plurality of columns 208 and to the third baseplate 510 connected to the third subset of the plurality of columns 209.

A polymer 400 is arranged between the carrier 100 and the first, second, and third baseplate (508, 509, 510), and between the first, second, and third subsets of the plurality of columns (207, 208, 209). The polymer 400 comprehensively covers the base surface of the carrier 100 where the plurality of columns are not arranged. The polymer 400 is between the plurality of columns 206 and between the carrier 100 and the first baseplate 508, the carrier 100 and the second baseplate 509, and the carrier 100 and the third baseplate 510. The polymer 400 is in direct contact with the base surface of the carrier 102 and the lateral surfaces 203 of the plurality of columns 206. The polymer 400 fixes the plurality of columns (206, 207, 208, 209) and increases their mechanical stability in that it laterally supports the plurality of columns (206, 207, 208, 209). The polymer end side 401 terminates flush with the carrier end side 103. For example, optoelectronic semiconductor devices 1 according to FIG. 7B are particularly space-saving and may be placed closer to one another and/or to other electronic components.

The exemplary embodiment shown in FIG. 7C essentially corresponds to the exemplary embodiment described in conjunction with FIG. 7B. In contrast thereto, the optoelectronic semiconductor device 1 is arranged on a substrate 500. In particular, the substrate 500 is a circuit board 503. The circuit board 503, on the side facing toward the first and second baseplates (508, 509), comprises a dielectric passivation layer 512 adhesively bonded on a metal core 516. The dielectric passivation layer 512 can be an FR4 circuit board. In particular, an adhesive layer 517 is provided between the dielectric passivation layer 512 and the metal core 516. The dielectric passivation layer 512 preferably comprises at least as many contact layers 513, 514, 515 as optoelectronic semiconductor devices 1 equipped on the circuit board 503 and first and second baseplates (508, 509) arranged on the optoelectronic semiconductor devices 1. The dielectric passivation layer 512 according to FIG. 7C comprises two contact layers 513. The first baseplate 508 is connected to a first contact layer 514 and the second baseplate 509 is connected to a second contact layer 515 on the dielectric passivation layer 512. The first contact layer 514 functions as an anode and the second contact layer 515 functions as a cathode. The baseplates (508, 509) are each connected using a solder layer 511 to the contact layers (514, 515). The third baseplate 510 is directly connected to the metal core 516. In particular, the third baseplate 510 is soldered using a solder layer 511 on the metal core 516. The solder layer 511 is arranged between the third baseplate 510 and the metal core 516. Alternatively, the third baseplate 510 can be connected to a contact layer 513 provided on the dielectric passivation layer 512.

According to FIG. 7C, the optoelectronic semiconductor device (1) comprises a first subset (207) of the plurality of columns (206), which adjoins the first electrical via (107), and a second subset (208) of the plurality of columns (206), which adjoins the second electrical via (108), wherein the first and second subset of the plurality of columns (207, 208) provide an electrical contact, wherein the first and second subset of the plurality of columns (207, 208) each comprise a baseplate (504), wherein a first baseplate (508) of the first subset of the plurality of columns (207) is soldered at a first contact layer (514), and a second baseplate (509) of the second subset of the plurality of columns (208) is soldered at a second contact layer (515) on the circuit board (503).

The exemplary embodiment shown in FIG. 8A essentially corresponds to the exemplary embodiment described in conjunction with FIG. 1. In contrast thereto, the optoelectronic semiconductor device 1 comprises a carrier 100 having precisely one column 200, wherein the one column 200 is arranged on a base surface of the carrier 102 opposite to the optoelectronic semiconductor chip 3. The one column 200 causes a thermal heat conduction away from the optoelectronic semiconductor chip 3 and the carrier 100. The one column 200 is arranged directly below the semiconductor chip 3 on the base surface of the carrier 102 opposite to the semiconductor chip 3. In particular, the center point of the one column 200 deviates by at most 500 μm, or at most 250 μm, or at most 100 μm, or at most 50 μm, or at most 20 μm from the center point of the optoelectronic semiconductor chip 3.

The one column 200 comprises an end cap 300 made of solder 302 on the end face 204, or on the end face 204 and at least partially the lateral surface 203.

The optoelectronic semiconductor device 1 according to the exemplary embodiment of FIG. 8B comprises an optoelectronic semiconductor device 1 according to FIG. 8A and a substrate 500. The optoelectronic semiconductor device 1 is soldered using the end cap 300 onto the one column 200 on a substrate 500. The substrate 500 can terminate flush with the end side of the carrier 103. Alternatively, the substrate 500 can protrude laterally beyond the carrier end side 103, in the direction away from the carrier end side 103. In particular, the substrate 500 is a heat sink 505 or a baseplate 504. If the substrate 500 is provided as a baseplate 504, it can preferably be soldered onto a heat sink 505 or circuit board 503.

The optoelectronic semiconductor device 1 comprises a polymer 400 between the carrier 100 and the substrate 500. The polymer 400 completely encloses the one column 200 and wets the base surface of the carrier 102 where the one column 200 is not arranged on the carrier 100. A polymer end side 401 terminates flush with the end sides of the carrier 103.

The invention is not restricted by the description on the basis of the exemplary embodiments. Rather, the invention comprises each novel feature and each combination of features, which in particular includes any combination of features in the claims, even if this feature or this combination itself is not explicitly specified in the claims or exemplary embodiments.

### LIST OF REFERENCE SIGNS

1 optoelectronic semiconductor device
2 upper side of the optoelectronic semiconductor device
3 optoelectronic semiconductor chip
4 upper side of the optoelectronic semiconductor chip
5 first electrical contact
6 second electrical contact
7 bond wire
9 molding compound
10 upper side of the molding compound
11 optical element
12 upper side of the optical element
13 connection layer
14 wall of the first electrical contact
15 wall of the second electrical contact
100 carrier
101 upper side of the carrier
102 base surface of the carrier
103 carrier end side
104 first contact pad
105 second contact pad
106 contact layer
107 first electrical via
108 second electrical via
200 one column
201 width of one column
202 height of one column
203 lateral surface of one column
204 end face of one column
205 column distance
206 plurality of columns
207 a first subset of the plurality of columns
208 a second subset of the plurality of columns
209 a third subset of the plurality of columns
210 electrically insulated subsets of columns
300 end cap
301 base surface of the end cap
302 solder
400 polymer
401 polymer end side
402 polymer material joint
403 polymer layer
404 polymer surface
500 substrate
501 upper side of the substrate
502 height between carrier and substrate
503 circuit board
504 baseplate
505 heat sink
506 upper side of the baseplate
507 lower side of the baseplate
508 first baseplate
509 second baseplate
510 third baseplate
511 solder layer
512 dielectric passivation layer
513 contact layer
514 first contact layer
515 second contact layer
516 metal core
517 adhesive layer

1. An optoelectronic semiconductor device having
a carrier,
an optoelectronic semiconductor chip arranged on the carrier, and
a plurality of columns, wherein the plurality of columns are arranged on a base surface of the carrier opposite to the optoelectronic semiconductor chip and wherein the plurality of columns cause a thermal heat conduction away from the optoelectronic semiconductor chip and the carrier,
wherein the plurality of columns,
each comprise an end face facing away from the base surface of the carrier, and
wherein a polymer is arranged between
the plurality of columns,
the base surface of the carrier and an upper side of a substrate, and
the end faces of the plurality of columns and the upper side of the substrate.

2. The optoelectronic semiconductor device according to claim 1, wherein one or more subsets of the plurality of columns provide an electrical contact of the optoelectronic semiconductor device.

3. The optoelectronic semiconductor device according to claim 1, wherein the plurality of columns comprises a metal including copper or a copper-containing alloy.

4. The optoelectronic semiconductor device according to claim 1, wherein at least one subset of the plurality of columns are arranged equidistantly from one another on the carrier.

5. The optoelectronic semiconductor device according to claim 1, wherein the plurality of columns are arranged in distinctly bounded electrically insulated subsets on the carrier.

6-19. (canceled)

20. A method for producing an optoelectronic semiconductor device, having the following steps:
a) providing a carrier;
b) applying a photoresist to a base surface of the carrier;
c) structuring the photoresist using photolithography;
d) exposing the base surface of the carrier by removing an exposed or unexposed area of the photoresist;
e) galvanically growing a plurality of columns on the base surface of the carrier in the exposed areas of the photoresist;
f) removing the photoresist;
g) providing at least one optoelectronic semiconductor chip arranged on the carrier;
h) isolating the carrier; and
i) fastening the optoelectronic semiconductor device on a substrate.

21. The method according to claim 20, wherein the optoelectronic semiconductor device in step i) is fastened using a polymer on an upper side of the substrate.

22. The method according to claim 20, wherein the plurality of columns in step e) are each provided with an end cap made of a solder.

23. The method according to claim 22, wherein the optoelectronic semiconductor device in step i) is soldered using the end caps on the upper side of the substrate.

24. The method according to claim 22, wherein a polymer is provided between the plurality of columns, wherein the end caps are present exposed from the polymer.

25. The method according to claim 24, wherein after step h), only one column is arranged on the carrier of the optoelectronic semiconductor device.
